(19) United States
(12) Patent Application Publication
(10) Pub. No.: US 2026/0164952 A1
(43) Pub. Date: Jun. 11, 2026

(54) DISPLAY DEVICE INCLUDING LIGHT-RECEIVING MODULE AND ELECTRONIC DEVICE INCLUDING THE SAME

(71) Applicant: SAMSUNG DISPLAY CO., LTD., YONGIN-SI (KR)

(72) Inventors: KWANGSOO LEE, Yongin-si (KR); KIWOOK KIM, Yongin-si (KR)

(21) Appl. No.: 19/294,539

(22) Filed: Aug. 8, 2025

(30) Foreign Application Priority Data
Dec. 10, 2024 (KR) 10-2024-0182914

(51) Int. Cl. H10K 59/124; H10K 59/121; H10K 59/126; H10K 59/131; H10K 59/35; H10K 59/65; H10K 59/88

(52) U.S. Cl. CPC H10K 59/124; H10K 59/1213; H10K 59/126; H10K 59/131; H10K 59/352; H10K 59/65; H10K 59/88

(57) ABSTRACT

A display device includes a substrate including a first display area with first and second pixel areas and a second display area. At least a portion of the second display area is surrounded by the first display area. The second display area includes a transmission area and a second pixel area. A first etch stop layer is disposed in the second pixel area. A first transistor is disposed in the second pixel area. A light-emitting element is disposed in the second pixel area on the first transistor, electrically connected to the first transistor, and including a pixel electrode, a light-emitting layer and a common electrode. An insulator is disposed in both the first display area and the second display area on the first etch stop layer, exposing an upper surface of the first etch stop layer, and defines a first dummy hole overlapping the pixel electrode.

### CROSS-REFERENCE TO RELATED APPLICATION(S)

This application claims priority under 35 U.S.C. § 119 to Korean Patent Application No. 10-2024-0182914, filed on Dec. 10, 2024, the content of which is herein incorporated by reference in its entirety.

### TECHNICAL FIELD

The present disclosure relates to a display device, and more particularly, to a display device having a functional module for receiving external light and the electronic device including the display device.

### DISCUSSION OF THE RELATED ART

A display device is a device that provides visual information to a user by emitting light. The display device includes a display area which emits light to display an image and a non-display area surrounding the display area. A plurality of pixels which emit light may be disposed inside the display area of the display device.

Recently, various functional modules that may be used with the display device have been added to the display device. For example, a user may take pictures, videos, or the like, by using a camera module disposed inside the display device. When the camera module is disposed in the non-display area of the display device, the size of the non-display area may be increased to secure space for the camera module to be disposed. Approaches for incorporating functional modules within the display area are therefore being considered.

### SUMMARY

A display device includes a substrate including a first display area that includes a first pixel area and a second display area. At least a portion of the second display area is surrounded by the first display area. The second display area includes a transmission area and a second pixel area. A first etch stop layer is disposed in the second pixel area on the substrate. A first transistor is disposed in the second pixel area on the substrate. A light-emitting element is disposed in the second pixel area on the first transistor, electrically connected to the first transistor, and including a pixel electrode, a light-emitting layer and a common electrode. An insulator is disposed in both the first display area and the second display area on the first etch stop layer, exposing an upper surface of the first etch stop layer, and defining a first dummy hole overlapping the pixel electrode, in a plan view.

The first dummy hole may be spaced apart from the transmission area, in the plan view.

The display device may further include a second etch stop layer disposed in the first pixel area on the substrate. In the insulator, a second dummy hole, which exposes an upper surface of the second etch stop layer and is disposed in the first pixel area, may be defined, and the first dummy hole disposed in the second pixel area may be part of a plurality of first dummy holes, the second dummy hole disposed in the first display area may be part of a plurality of second dummy holes, and a number of first dummy holes of the plurality of first dummy holes may be greater than a number of second dummy holes of the plurality of second dummy holes.

The first transistor may include a first active layer disposed on the substrate, a first gate electrode disposed on the first active layer, a first source electrode disposed on the first gate electrode, and a first drain electrode disposed on the first gate electrode.

The insulator may include a gate insulating layer disposed on the first active layer and an interlayer insulating layer disposed on the first gate electrode.

The first etch stop layer may be disposed in a same layer as the first active layer, and the first dummy hole may penetrate the gate insulating layer and the interlayer insulating layer in a thickness direction.

The first etch stop layer may be disposed in a same layer as the first gate electrode, and the first dummy hole may penetrate the interlayer insulating layer in a thickness direction.

The first source electrode and the first drain electrode may contact the first active layer through a contact hole which penetrates the gate insulating layer and the interlayer insulating layer in a thickness direction, and in the plan view, a size of the contact hole may be less than a size of the first dummy hole.

The first source electrode and the first drain electrode may contact the first active layer through a contact hole which penetrates the gate insulating layer and the interlayer insulating layer in a thickness direction, and, in the plan view, a size of the contact hole may be greater than a size of the first dummy hole.

The display device of may further include a second transistor disposed in the second pixel area on the substrate and a third etch stop layer disposed in the second pixel area on the substrate. The second transistor may include a second active layer disposed on the first source electrode and the first drain electrode, a second gate electrode disposed on the second active layer, a second source electrode disposed on the second gate electrode, and a second drain electrode disposed on the second gate electrode.

The insulator may include a first gate insulating layer disposed on the first active layer, a first interlayer insulating layer disposed on the first gate electrode, a second gate insulating layer disposed on the second active layer, and a second interlayer insulating layer disposed on the second gate insulating layer. A third dummy hole, which penetrates at least a portion of the insulator in a thickness direction and exposes an upper surface of the third etch stop layer, may be defined in the insulator.

The first etch stop layer may be disposed in a same layer as the first active layer, and the first dummy hole may penetrate the first gate insulating layer, the first interlayer insulating layer, the second gate insulating layer, and the second interlayer insulating layer in a thickness direction.

The first etch stop layer may be disposed in a same layer as the first gate electrode, and the first dummy hole may penetrate the first interlayer insulating layer, the second gate insulating layer, and the second interlayer insulating layer in a thickness direction.

The third etch stop layer may be disposed in a same layer as the second active layer, and the third dummy hole may penetrate the second gate insulating layer and the second interlayer insulating layer in a thickness direction.

The third etch stop layer may be disposed in a same layer as the second gate electrode, and the third dummy hole may penetrate the second interlayer insulating layer in a thickness direction.

A display device includes a substrate including a first display area that includes a first pixel area and a second display area. At least a portion of the second display area is surrounded by the first display area, and the second display area includes a transmission area and a second pixel area. An etch stop layer is disposed in the second pixel area on the substrate. A transistor is disposed in the second pixel area on the substrate. A light-emitting element is disposed in the second pixel area on the transistor, electrically connected to the transistor, and including a pixel electrode, a light-emitting layer, and a common electrode. A plurality of light blockers is disposed in the first display area and the second display area on the light-emitting element. An insulator is disposed in the first display area and the second display area on the etch stop layer and in which a dummy hole, which exposes an upper surface of the etch stop layer and overlaps the plurality of light blockers in a plan view, is defined.

The display device may further include a plurality of gate lines disposed in both the first display area and the second display area on the substrate, and extending in a first direction, and a plurality of data lines disposed in the first display area and the second display area on the substrate, and extending in a second direction crossing the first direction. The dummy hole may be spaced apart from the plurality of gate lines and the plurality of data lines, in the plan view.

An electronic device includes a housing, a display device housed in the housing, configured to display an image, and including a substrate including a first display area that includes a first pixel area and a second display area, wherein at least a portion of the second display area is surrounded by the first display area, and wherein the second display area includes a transmission area and a second pixel area. A etch stop layer is disposed in the second pixel area on the substrate. A transistor is disposed in the second pixel area on the substrate. Aa light-emitting element is disposed in the second pixel area on the transistor, electrically connected to the transistor, and including a pixel electrode, a light-emitting layer, and a common electrode. A plurality of light blockers is disposed in the first display area and the second display area, on the light-emitting element. An insulator is disposed in the first display area and the second display area on the etch stop layer and in which a first dummy hole, which exposes an upper surface of the etch stop layer, and overlaps the plurality of light blockers in a plan view or overlaps the plurality of light blockers, is defined. A cover window covers the display device.

The first dummy hole may be spaced apart from the transmission area in the plan view.

The display device may further include a second etch stop layer disposed in the first pixel area on the substrate, wherein a second dummy hole, which exposes an upper surface of the second etch stop layer and disposed in the first pixel area, is defined in the insulator. The first dummy hole may be disposed in the second display area is part of a plurality of first dummy holes. The second dummy hole disposed in the first display area may be part of a plurality of second dummy holes, and a number of the first dummy holes of the plurality of first dummy holes may be greater than a number of second dummy holes of the plurality of second dummy holes.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a block diagram illustrating a display device according to an embodiment of the disclosure.

FIG. 2 is a plan view illustrating an example of the display device of FIG. 1.

FIG. 3 is a circuit diagram illustrating a first sub-pixel included in the display device of FIG. 2.

FIG. 4 is a cross-sectional view illustrating a cross-section of a portion of the display device of FIG. 2.

FIG. 5 is a plan view illustrating a first display area of the display device of FIG. 2.

FIG. 6 is a cross-sectional view illustrating an example of a cross-section taken along line I-I′ of FIG. 5.

FIG. 7 is a cross-sectional view illustrating an example of a cross-section taken along line I-I′ of FIG. 5.

FIG. 8 is a plan view illustrating a second display area of the display device of FIG. 2.

FIG. 9 is a plan view illustrating an example in which an area A of FIG. 8 is enlarged.

FIG. 10 is a cross-sectional view illustrating an example of a cross-section taken along line II-II′ of FIG. 9.

FIG. 11 is a cross-sectional view illustrating an example of a cross-section taken along line II-II′ of FIG. 9.

FIG. 12 is a cross-sectional view illustrating still an example of a cross-section taken along line II-II′ of FIG. 9.

FIG. 13 is a cross-sectional view illustrating still an example of a cross-section taken along line II-II′ of FIG. 9.

FIG. 14 is a plan view illustrating an example in which area A of FIG. 8 is enlarged.

FIG. 15 is a plan view illustrating still an example in which area A of FIG. 8 is enlarged.

FIG. 16 is a cross-sectional view illustrating a cross-section taken along line III-III′ of FIG. 15.

FIG. 17 is a plan view illustrating an example of the display device of FIG. 1.

FIG. 18 is a circuit diagram illustrating a first sub-pixel included in the display device of FIG. 17.

FIG. 19 is a cross-sectional view illustrating a cross-section in the first display area of the first sub-pixel included in the display device of FIG. 17.

FIG. 20 is a cross-sectional view illustrating an example of a cross-section in the second display area of the first sub-pixel included in the display device of FIG. 17.

FIG. 21 is a cross-sectional view illustrating an example of a cross-section in the second display area of the first sub-pixel included in the display device of FIG. 17.

FIG. 22 is a cross-sectional view illustrating still an example of a cross-section in the second display area of the first sub-pixel included in the display device of FIG. 17.

FIG. 23 is a cross-sectional view illustrating still an example of a cross-section in the second display area of the first sub-pixel included in the display device of FIG. 17.

FIG. 24 is a block diagram illustrating an electronic device according to an embodiment of the disclosure.

FIG. 25 is a diagram illustrating an example in which the electronic device of FIG. 24 is implemented as a smartphone.

### DETAILED DESCRIPTION OF THE EMBODIMENTS

In describing embodiments of the present disclosure illustrated in the drawings, specific terminology is employed for sake of clarity. However, the present disclosure is not necessarily intended to be limited to the specific terminology so selected, and it is to be understood that each specific element includes all technical equivalents which operate in a similar manner.

The disclosure is capable of various modifications and various forms, and specific embodiments are illustrated in the drawings and described in detail herein. However, this is not necessarily intended to limit the disclosure to particular modes of disclosure, but it is to be understood that the disclosure includes all modifications, equivalents, and alternatives that fall within the spirit and technical scope of the disclosure.

Terms such as first, second, and the like may be used to describe various configurations, but the configurations should not necessarily be limited by these terms. These terms are used to distinguish one configuration from another. For example, a first configuration may be termed a second configuration without departing from the scope of the disclosure, and similarly, a second configuration may also be termed a first configuration.

When a configuration is referred to as being “connected” or “coupled” to another configuration, it should be understood that it may be directly connected or coupled to the other configuration, or one or more other configurations may be interposed therebetween. On the other hand, when a configuration is referred to as being “directly connected” or “directly coupled” to another configuration, it should be understood that there is no other configuration interposed therebetween. Other expressions describing the relationships between configurations such as “between” and “immediately between” or “adjacent to” and “directly adjacent to” should be interpreted in the same way.

The terminology used in the present application is for the purpose of describing particular embodiments only and is not necessarily intended to be limiting of the disclosure. Unless the context clearly indicates otherwise, the singular forms include plural referents. In the present application, the terms “comprise,” “include,” “have,” and any variations thereof are intended to specify the presence of stated features, numbers, steps, operations, configurations, parts, or combinations thereof, but do not preclude the presence or addition of one or more other features, numbers, steps, operations, configurations, parts, or combinations thereof.

In cases where an embodiment may be implemented differently, functions or operations specified in a particular block may occur in an order different from that specified in a flowchart. For example, two consecutive blocks may actually be performed substantially simultaneously, or the blocks may be performed in reverse order depending on the relevant functions or operations.

Hereinafter, embodiments of the disclosure will be described in more detail with reference to the accompanying drawings. The same reference numerals may be used for the same configurations in the specification and drawings, and to the extent that an element is not described in detail with respect to this figure, it may be understood that the element is at least similar to a corresponding element that has been described elsewhere within the present disclosure.

Embodiments of the present disclosure relate to a display device which integrates functional optical modules such as cameras into the display area itself, rather than the surrounding non-display bezel. To achieve this, the device incorporates a special second display area embedded within the main display that includes both pixels for image display and transmission zones for allowing light to reach the underlying module.

An aspect of this arrangement involves the strategic use of “dummy holes” that expose portions of an etch stop layer within the multilayer structure of the display panel. These dummy holes are engineered to mitigate electrical instability issues, particularly those related to hydrogen diffusion from insulating materials into the active layer of transistors. By placing these dummy holes in specific patterns and maintaining separation from signal-carrying lines like gate and data lines, the design stabilizes the threshold voltage and preserves the hysteresis characteristics of the transistors, thereby enhancing display reliability and quality.

Furthermore, multiple layers and materials, such as pixel electrodes, light-emitting layers, and encapsulation structures, may be disposed to optimize light transmission and minimize distortion or interference. Notably, the dummy holes may be aligned with pixel electrodes or light-blocking layers in a way that prevents external light distortion, preserving the clarity of the captured images or detected signals. These design elements together make it possible to integrate high-function optical modules within the active display without degrading image quality or increasing device size.

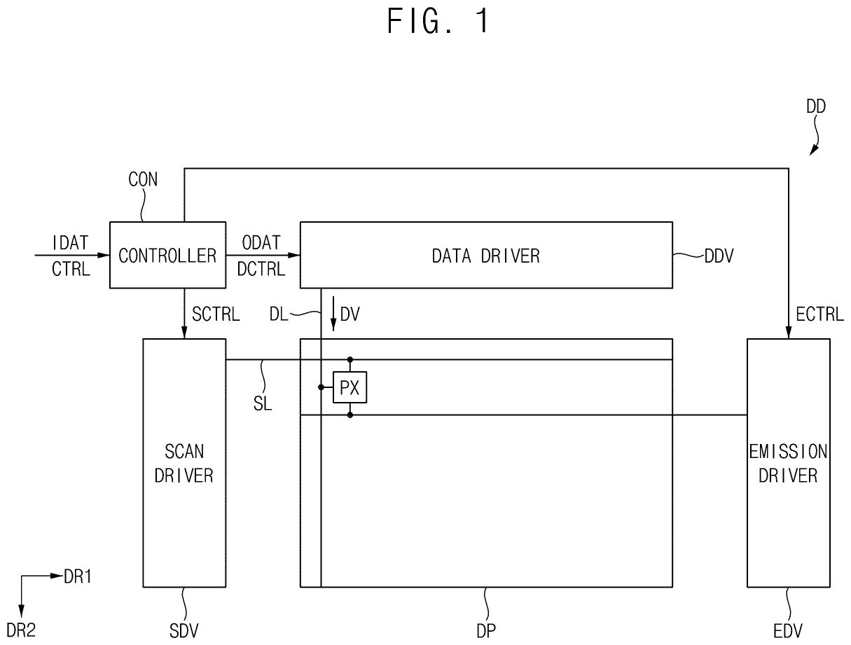

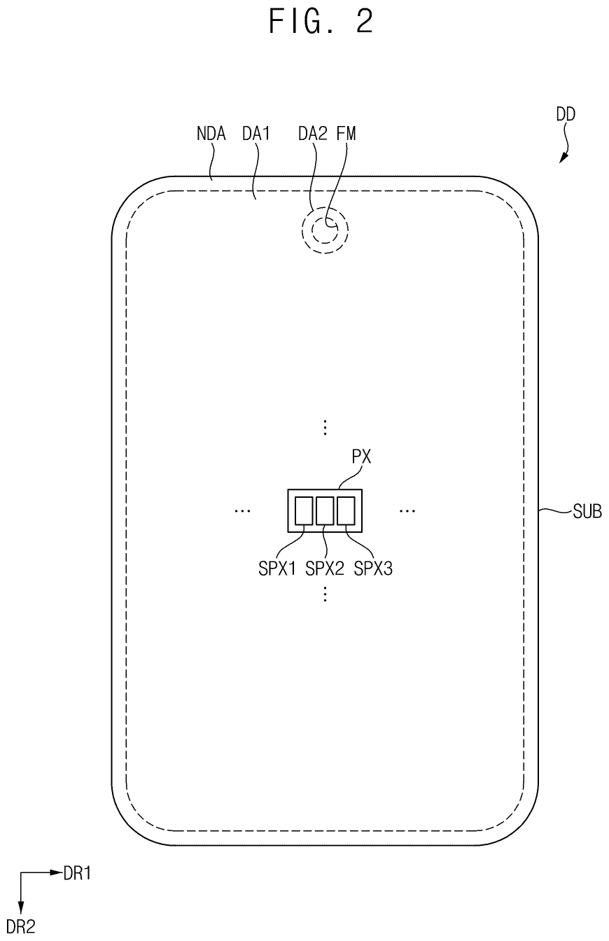

FIG. 1 is a block diagram illustrating a display device according to an embodiment of the disclosure. FIG. 2 is a plan view illustrating an example of the display device of FIG. 1.

Referring to FIGS. 1 and 2, a display device DD may include a display panel DP and a display panel driver. The display panel driver may include a driving controller CON, a scan driver SDV, a light-emitting driver EDV, and a data driver DDV. The display device DD may further include a substrate SUB and a functional module FM.

The display device DD may include a first display area DA1, a second display area DA2, and a non-display area NDA. As the display device DD may include the first display area DA1, the second display area DA2, and the non-display area NDA, the substrate SUB may also include the first display area DA1, the second display area DA2, and the non-display area NDA.

In the disclosure, a plane may be defined by a first direction DR1 and a second direction DR2 intersecting the first direction DR1. For example, the first direction DR1 and the second direction DR2 may be perpendicular to each other.

The first display area DA1 may be an area configured to display an image by generating light or adjusting a transmittance of light provided from an external light source. At least one pixel PX that emits light may be disposed in the first display area DA1. A plurality of pixels PX may be disposed in the first display area DA1. For example, the pixels PX may be disposed in the first display area DA1 and the second display area DA2 in the first direction DR1 and the second direction DR2 to form a matrix.

In an embodiment, the pixel PX may include sub-pixels that emit light of different colors. For example, the sub-pixels may include a first sub-pixel SPX1, a second sub-pixel SPX2, and a third sub-pixel SPX3. The first sub-pixel SPX1, the second sub-pixel SPX2, and the third sub-pixel SPX3 may emit light of different colors. For example, the first sub-pixel SPX1 may emit light of a first color, the second sub-pixel SPX2 may emit light of a second color, and the third sub-pixel SPX3 may emit light of a third color. In an embodiment, the first color may be red, the second color may be green, and the third color may be blue. The colors of light emitted from the sub-pixels included in the pixel PX according to embodiments of the disclosure may not necessarily be limited to thereto and may include various colors such as magenta, cyan, and yellow.

In an embodiment, at least a portion of the second display area DA2 may be surrounded by the first display area DA1. For example, in a plan view, the first display area DA1 may entirely surround a boundary of the second display area DA2. In an embodiment, the second display area DA2 may be disposed at a center upper portion of the first display area DA1. A location of the second display area DA2, according to embodiments of the disclosure, may not necessarily be limited thereto and may be disposed at the upper left or upper right of the first display area DA1.

In an embodiment, the second display area DA2 may have a circular shape in a plan view. A shape of the second display area DA2, according to embodiments of the disclosure, is not necessarily limited thereto and may have an elliptical or polygonal shape in a plan view.

At least one pixel PX that may emit light may be disposed in the second display area DA2. In the component area CA, the pixels PX may be repeatedly disposed in the first direction DR1 and the second direction DR2. In an embodiment, a number of pixels PX disposed in the second display area DA2 may be smaller than a number of pixels PX disposed in the first display area DA1.

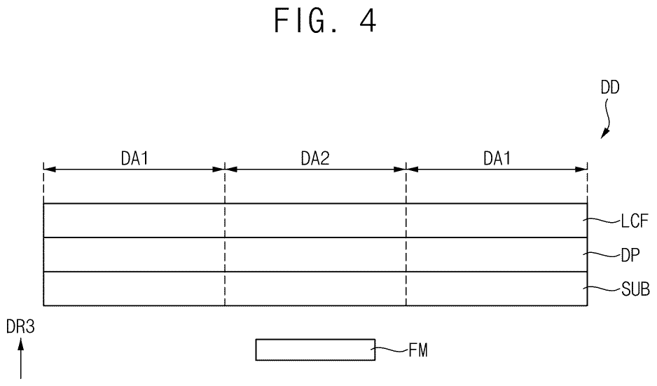

The functional module FM may be disposed in the second display area DA2. For example, the functional module FM may be disposed under the substrate SUB corresponding to the second display area DA2. The functional module FM may receive light passing through the second display area DA2. A description of the functional module FM will be described later with reference to FIG. 4.

At least of a portion of the non-display area NDA may surround the first display area DA1. For example, the non-display area NDA may entirely surround the first display area DA1 in a plan view. The non-display area NDA may be defined as an area that does not emit light and does not generate images. The display panel driver for driving the pixels PX may be disposed in the non-display area NDA. The display panel driver may provide signals and/or voltages to the pixels PX. For example, the driving controller CON, the scan driver SDV, the light-emitting driver EDV, and the data driver DDV may be disposed in the non-display area NDA. The display panel driver disposed in the non-display area NDA may not necessarily be limited thereto and may further include a power voltage supplier for supplying power voltage to the pixels PX, a demultiplexer circuit for connecting the pixels PX and a plurality of data lines DL.

In an embodiment, the pixel PX may be electrically connected to a plurality of scan lines SL, a plurality of light-emitting lines EL, and a plurality of data lines DL. Each of the plurality of scan lines SL may extend from the scan driver SDV, each of the plurality of light-emitting lines EL may extend from the light-emitting driver EDV, and each of the plurality of data lines DL may extend from the data driver DDV. In the disclosure, the plurality of scan lines SL and the plurality of light-emitting lines EL may be referred to as gate lines.

Each of the plurality of scan lines SL may extend in the first direction DR1. Each of the plurality of scan lines SL may be spaced apart from each other in the second direction DR2. Each of the plurality of data lines DL may extend in the second direction DR2. Each of the plurality of data lines DL may be spaced apart from each other in the first direction DR1. Each of the plurality of light-emitting lines EL may extend in the first direction DR1. Each of the plurality of light-emitting lines EL may be spaced apart from each other in the second direction DR2.

The driving controller CON may receive an input image data IDAT and an input control signal CTRL from an external device such as a host processor (e.g., a graphic processing unit “GPU”). In an embodiment, the input image data IDAT may include red image data, green image data, and blue image data. The input image data IDAT, according to embodiments of the disclosure, may not necessarily be limited thereto.

In an embodiment, the input image data IDAT may further include white image data. In an embodiment, the input image data IDAT may include magenta image data, yellow image data, and cyan image data. The input control signal CTRL may include a master clock signal and a data enable signal. The input control signal CTRL may further include a vertical sync signal and a horizontal sync signal.

The driving controller CON may generate a scan control signal SCTRL, a data control signal DCTRL, a light-emitting control signal ECTRL, and output data signals ODAT based on the input image data IDAT and the input control signal CTRL.

The driving controller CON may generate a scan control signal SCTRL to control the operation of the scan driver SDV based on the input control signal CTRL. The driving controller CON may output the scan control signal SCTRL to the scan driver SDV. The scan control signal SCTRL may include a vertical start signal and a scan clock signal.

The driving controller CON may generate a light-emitting control signal ECTRL to control the operation of the light-emitting driver EDV based on the input control signal CTRL. The driving controller CON may output the light-emitting control signal ECTRL to each of the plurality of light-emitting lines EL.

The driving controller CON may generate a data control signal DCTRL to control an operation of the data driver DDV based on the input control signal CTRL. The driving controller CON may output the data control signal DCTRL to the data driver DDV. The data control signal DCTRL may include a horizontal start signal and a load signal.

The driving controller CON may generate output data signals ODAT based on the input image data IDAT. The driving controller CON may output the output data signals ODAT to the data driver DDV.

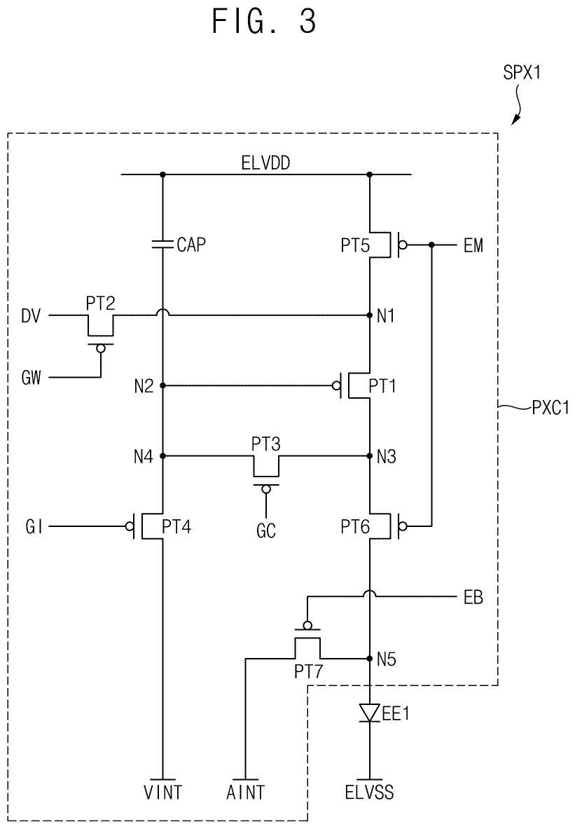

The scan driver SDV may output signals for driving the pixels PX to each of the plurality of scan lines SL based on the scan control signals SCTRL received from the driving controller CON. The light-emitting driver EDV may output light-emitting signals (e.g., the light-emitting signal EM of FIG. 3) to each of the plurality of light-emitting lines EL based on the light-emitting control signal ECTRL. The data driver DDV may output data voltages DV to each of the plurality of data lines DL based on the output data signals ODAT and the data control signal DCTRL.

FIG. 3 is a circuit diagram illustrating a first sub-pixel included in the display device of FIG. 2.

Referring to FIGS. 2 and 3, the first sub-pixel SPX1 may include the first pixel circuit portion PXC1 and the first light-emitting element EE1. The first pixel circuit portion PXC1 may include a first pixel transistor PT1, a second pixel transistor PT2, a third pixel transistor PT3, a fourth pixel transistor PT4, a fifth pixel transistor PT5, a sixth pixel transistor PT6, a seventh pixel transistor PT7, and a storage capacitor CAP.

The first pixel transistor PT1 may include a first terminal connected to the first node N1, a gate terminal connected to the second node N2, and a second terminal connected to the third node N3. The first terminal of the first pixel transistor PT1 may be electrically connected to a data line applied (e.g., a plurality of data lines DL of FIG. 1) to which a data voltage DV is. Accordingly, the first pixel transistor PT1 may generate a driving current corresponding to the data voltage DV. The driving current may be provided to the first light-emitting element EE1. The first pixel transistor PT1 may be referred to as a driving transistor.

The second pixel transistor PT2 may include a first terminal connected to the data line, a second terminal connected to the first node N1, and a gate terminal receiving a gate write signal GW. Accordingly, the second pixel transistor PT2 may be turned on or off by the gate write signal GW. During a period in which the second pixel transistor PT2 is turned on, the second pixel transistor PT2 may provide the data voltage DV to the first pixel transistor PT1. For example, the second pixel transistor PT2 may transfer the data voltage DV to the first node N1 in response to the gate write signal GW. The second pixel transistor PT2 may be referred to as a data write transistor.

The third pixel transistor PT3 may include a first terminal connected to the third node N3, a second terminal connected to the fourth node N4, and a gate terminal receiving a gate compensation signal GC. Accordingly, the third pixel transistor PT3 may be turned on or off by the gate compensation signal GC. During a period in which the third pixel transistor PT3 is turned on, the third pixel transistor PT3 may compensate for a threshold voltage of the first pixel transistor PT1 by diode-connecting the first pixel transistor PT1. The third pixel transistor PT3 may be referred to as a compensation transistor.

The fourth pixel transistor PT4 may include a first terminal connected to the fourth node N4, a second terminal connected to the first initialization voltage line, and a gate terminal receiving a gate initialization signal GI. Accordingly, the fourth pixel transistor PT4 may be turned on or off by the gate initialization signal GI. During a period in which the fourth pixel transistor PT4 is turned on, the fourth pixel transistor PT4 may provide a first gate initialization voltage VINT supplied from the first initialization voltage line to the gate terminal of the first pixel transistor PT1. The fourth pixel transistor PT4 may be referred to as an initialization transistor.

The fifth pixel transistor PT5 may include a first terminal connected to the first power voltage line, a second terminal connected to the first node N1, and a gate terminal connected to a light-emitting line (e.g., a plurality of light-emitting lines EL in FIG. 1). The light-emitting line may provide a light-emitting signal EM to the gate terminal of the fifth pixel transistor PT5. Accordingly, the fifth pixel transistor PT5 may be turned on or off by the light-emitting signal EM. During a period in which the fifth pixel transistor PT5 is turned on, the fifth pixel transistor PT5 may provide a first power voltage ELVDD supplied from the first power voltage line to the first pixel transistor PT1.

In an embodiment, each of the first power voltage ELVDD supplied from the first power voltage line and a second power voltage ELVSS supplied from a second power voltage line connected to the first light-emitting element EE1 may be a constant voltage. In the case, the first power voltage ELVDD and the second power voltage ELVSS may have different voltage levels.

The sixth pixel transistor PT6 may include a first terminal connected to the third node N3, a second terminal connected to the fifth node N5, and a gate terminal connected to the light-emitting line. Accordingly, the sixth pixel transistor PT6 may be turned on or off by the light-emitting signal EM. During a period in which the sixth pixel transistor PT6 is turned on, the sixth pixel transistor PT6 may provide the driving current to the first light-emitting element EE1.

The seventh pixel transistor PT7 may include a first terminal connected to the second initialization voltage line, a second terminal connected to the fifth node N5, and a gate terminal receiving a bypass signal EB. Accordingly, the seventh pixel transistor PT7 may be turned on or off by the bypass signal EB. During a period in which the seventh pixel transistor PT7 is turned on, the seventh pixel transistor PT7 may provide a second gate initialization voltage AINT supplied from the second initialization voltage line to the first light-emitting element EE1.

The storage capacitor CAP may include a first terminal connected to the second node N2 and a second terminal connected to the first power voltage line. The storage capacitor CAP may maintain the voltage level of the gate terminal of the first pixel transistor PT1 during an inactive period of the gate write signal GW.

The first light-emitting element EE1 may include a first terminal (e.g., an anode terminal) and a second terminal (e.g., a cathode terminal). The first terminal of the light-emitting element EE1 may be connected to the sixth pixel transistor PT6 and the seventh pixel transistor PT7, and the second terminal may receive the second power voltage ELVSS. The first light-emitting element EE1 may generate light with luminance corresponding to the driving current.

In an embodiment, each of the first pixel transistor PT1, the second pixel transistor PT2, the fifth pixel transistor PT5, the sixth pixel transistor PT6, and the seventh pixel transistor PT7 may be a PMOS transistor.

In an embodiment, the gate write signal GW, the gate compensation signal GC, the gate initialization signal GI, the light-emitting signal EM, and the bypass signal EB for turning on each of the second transistor T2, the third transistor T3, the fourth transistor T4, the fifth transistor T5, the sixth transistor T6, and the seventh transistor T7 may have a negative voltage level. Types of each of the first, second, third, fourth, fifth, sixth, and seventh pixel transistors PT1, PT2, PT3, PT4, PT5, PT6, and PT7 and the voltage levels of signals applied to gate terminals of transistors according to embodiments of the disclosure may not necessarily be limited thereto. For example, at least one of the first, second, third, fourth, fifth, sixth, and seventh pixel transistors PT1, PT2, PT3, PT4, PT5, PT6, and PT7 may be an NMOS transistor.

Although FIG. 3 illustrates the structure of the first sub-pixel SPX1, each of the second sub-pixel SPX2 and the third sub-pixel SPX3 may have substantially a same structure as the first sub-pixel SPX1.

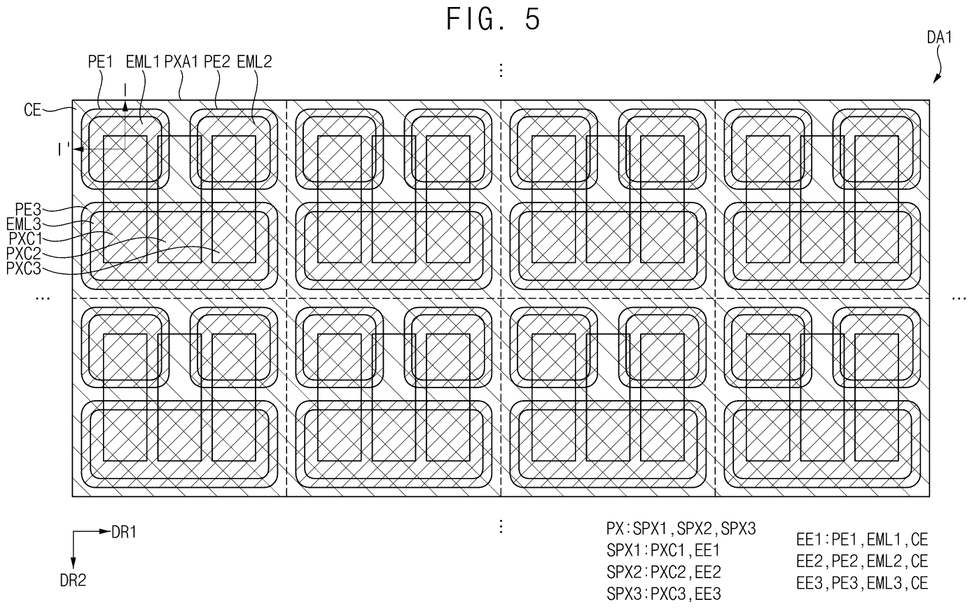

For example, each of the second pixel circuit portion (e.g., the second pixel circuit portion PXC2 of FIG. 5) included in the second sub-pixel SPX2 and the third pixel circuit portion (e.g., the third pixel circuit portion PXC3 of FIG. 5) included in the third sub-pixel SPX3 may be substantially a same as the first pixel circuit portion PXC1.

For example, the second light-emitting element (e.g., the second light-emitting element EE2 of FIG. 5) included in the second sub-pixel SPX2 and the third light-emitting element (e.g., the third light-emitting element EE3 of FIG. 5) included in the third sub-pixel SPX3 may be substantially a same as the first light-emitting element EE1, except that the second light-emitting element emit different color from the first light-emitting element EE1.

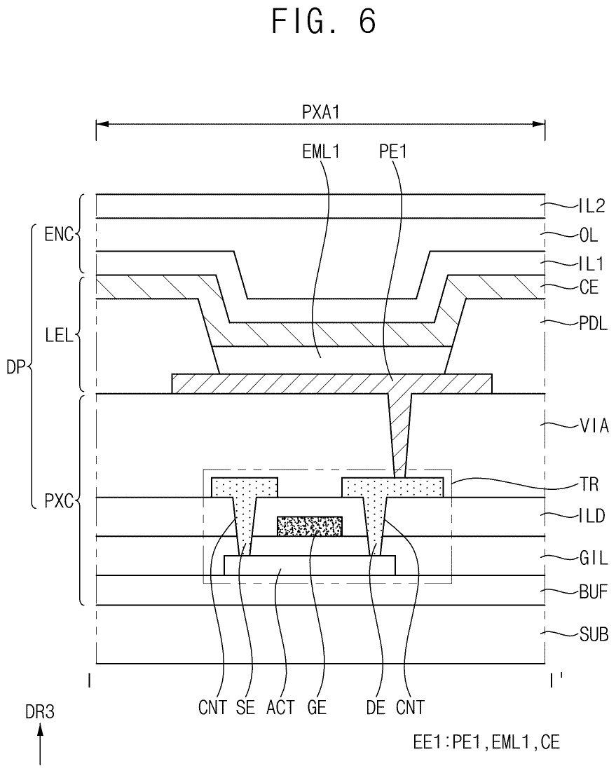

FIG. 4 is a cross-sectional view illustrating a cross-section of a portion of the display device of FIG. 2. FIG. 5 is a plan view illustrating a first display area of the display device of FIG. 2. FIG. 6 is a cross-sectional view illustrating an example of a cross-section taken along line I-I′ of FIG. 5.

Referring to FIGS. 4, 5, and 6, the display device DD may include a substrate SUB, a display panel DP, a light control film LCF, and a functional module FM. The display panel DP may include the substrate SUB, a buffer layer BUF, an active layer ACT, a gate insulating layer GIL, a gate electrode GE, an interlayer insulating layer ILD, a source electrode SE, a drain electrode DE, a via insulating layer VIA, a first pixel electrode PE1, a second pixel electrode PE2, a third pixel electrode PE3, a pixel defining layer PDL, a first light-emitting layer EML1, a second light-emitting layer EML2, a third light-emitting layer EML3, a common electrode CE, a first inorganic encapsulation layer IL1, an organic encapsulation layer OL, and a second inorganic encapsulation layer IL2.

The active layer ACT, the gate electrode GE, the source electrode SE, and the drain electrode DE may together define a transistor TR. The transistor TR may correspond to one of the first to seventh pixel transistors PT1, PT2, PT3, PT4, PT5, PT6, PT7 illustrated in FIG. 3. The transistor TR, according to an embodiment of the present disclosure, may not necessarily be limited thereto, and each of the first to fifth pixel transistors PT1, PT2, PT3, PT4, PT5 and the seventh pixel transistor PT7 may have a substantially same structure as the transistor TR.

The buffer layer BUF, the active layer ACT, the gate insulating layer GIL, the gate electrode GE, the interlayer insulating layer ILD, the source electrode SE, the drain electrode DE, and the via insulating layer VIA may define a pixel circuit layer PXC. The pixel circuit layer PXC may include a first pixel circuit portion PXC1, a second pixel circuit portion PXC2, and a third pixel circuit portion PXC3.

The first pixel electrode PE1, the second pixel electrode PE2, the pixel defining layer PDL, the third pixel electrode PE3, the first light-emitting layer EML1, the second light-emitting layer EML2, the third light-emitting layer EML3, and the common electrode CE may define a light-emitting element layer LEL. The first pixel electrode PE1, the first light-emitting layer EML1, and the common electrode CE may define a first light-emitting element EE1. The second pixel electrode PE2, the second light-emitting layer EML2, and the common electrode CE may define a second light-emitting element EE2. The third pixel electrode PE3, the third light-emitting layer EML3, and the common electrode CE may define a third light-emitting element EE3. The first inorganic encapsulation layer IL1, the organic encapsulation layer OL, and the second inorganic encapsulation layer IL2 may define an encapsulation layer ENC.

The first light-emitting element EE1 may be electrically connected to the first pixel circuit portion PXC1. For example, the first light-emitting element EE1 may be electrically connected to the transistor TR included in the first pixel circuit portion PXC1. The second light-emitting element EE2 may be electrically connected to the second pixel circuit portion PXC2. For example, the second light-emitting element EE2 may be electrically connected to the transistor included in the second pixel circuit portion PXC2. The third light-emitting element EE3 may be electrically connected to the third pixel circuit portion PXC3. For example, the third light-emitting element EE3 may be electrically connected to the transistor included in the third pixel circuit portion PXC3.

The first display area DA1 may define a first pixel area PXA1 in which one of the pixels (e.g., the pixel PX of FIG. 1) is disposed. For example, one of first pixel area PXA1 may have each of a first sub-pixel SPX1, a second sub-pixel SPX2, and a third sub-pixel SPX3 disposed therein. The first pixel area PXA1 may be repeatedly disposed in the first display area DA1 along the first direction DR1 and the second direction DR2.

The substrate SUB may serve as a base of the display panel DP. The substrate SUB may include a transparent or opaque material. The substrate SUB may include glass, quartz, plastic, and the like. For example, the plastic may include polyimide (PI), polyethylene naphthalate (PEN), polyethylene terephthalate (PET), polycarbonate (PC), polyetherimide (PEI), polyethersulfone (PS), and the like. These may be used alone or in combination with each other.

The buffer layer BUF may be disposed on the substrate SUB. The buffer layer BUF may prevent metal atoms or impurities from diffusing from the substrate SUB into the active layer ACT. In addition, the buffer layer BUF may control a rate of heat transfer during a crystallization process for forming the active layer ACT.

The active layer ACT may be disposed on the buffer layer BUF. The active layer ACT may include amorphous silicon, polycrystalline silicon, or an oxide semiconductor. The active layer ACT may include a source area and a drain area doped with impurities, and a channel area disposed between the source area and the drain area.

The gate insulating layer GIL may be disposed on the active layer ACT. The gate insulating layer GIL may cover the active layer ACT on the buffer layer BUF. For example, the gate insulating layer GIL may sufficiently cover the active layer ACT and may have a substantially flat upper surface without forming a step around the active layer ACT. The gate insulating layer GIL, according to embodiments of the disclosure, may not necessarily be limited thereto, and the gate insulating layer GIL may have a substantially uniform thickness along the profile of the active layer ACT.

In an embodiment, the gate insulating layer GIL may include an inorganic insulating material. The inorganic insulating material may include silicon nitride SiNₓ, silicon oxide SiOₓ, silicon oxynitride SiOₓN_{y}, and the like. These may be used alone or in combination with one another.

The gate electrode GE may be disposed on the gate insulating layer GIL. The gate electrode GE may overlap the channel area of the active layer ACT in a plan view. The gate electrode GE may include metal, alloy, conductive metal oxide, conductive metal nitride, transparent conductive material, and the like. These may be used alone or in combination with one another.

The interlayer insulating layer ILD may be disposed on the gate electrode GE. The interlayer insulating layer ILD may cover the gate electrode GE on the gate insulating layer GIL. For example, the interlayer insulating layer ILD may sufficiently cover the gate electrode GE and may have a substantially flat upper surface without forming a step around the gate electrode GE. The interlayer insulating layer ILD, according to embodiments of the disclosure, may not necessarily be limited thereto, and the interlayer insulating layer ILD may have a substantially uniform thickness following the profile of the gate electrode GE.

In an embodiment, the interlayer insulating layer ILD may have a multilayer structure. For example, when the interlayer insulating layer ILD has a multilayer structure, an electrode layer defining a storage capacitor together with the gate electrode GE may be further disposed in the interlayer insulating layer ILD. The interlayer insulating layer ILD according to embodiments of the disclosure may not necessarily be limited thereto.

The source electrode SE and the drain electrode DE may be disposed on the interlayer insulating layer ILD. In an embodiment, the source electrode SE and the drain electrode DE may contact the source area and the drain area of the active layer ACT, respectively. For example, the source electrode SE and the drain electrode DE may be in contact with the source area and the drain area through a contact hole CNT penetrating the gate insulating layer GIL and the interlayer insulating layer ILD in a thickness direction (e.g., a third direction DR3). In an embodiment, the source electrode SE and the drain electrode DE may include metal, an alloy, a conductive metal oxide, a conductive metal nitride, a transparent conductive material, and the like. These may be used alone or in combination with one another.

The via insulating layer VIA may be disposed on the source electrode SE and the drain electrode DE. A hole for exposing an upper surface of the drain electrode DE may be defined in the via insulating layer VIA. The via insulating layer VIA, according to embodiments of the disclosure, may not necessarily be limited thereto. For example, the hole defined in the via insulating layer VIA may expose an upper surface of the source electrode SE. In an embodiment, the via insulating layer VIA may have a substantially upper top surface. In an embodiment, the via insulating layer VIA may include an organic insulating material such as a polyimide.

The first pixel circuit portion PXC1, the second pixel circuit portion PXC2, and the third pixel circuit portion PXC3 may each be disposed in the first pixel area PXA1. In an embodiment, the first pixel circuit portion PXC1, the second pixel circuit portion PXC2, and the third pixel circuit portion PXC3 may be spaced apart from each other in a plan view. For example, the first pixel circuit portion PXC1, the second pixel circuit portion PXC2, and the third pixel circuit portion PXC3 may be spaced apart from each other in the first direction DR1 in a plan view.

In an embodiment, the first pixel circuit portion PXC1, the second pixel circuit portion PXC2, and the third pixel circuit portion PXC3 may be sequentially disposed in a first direction DR1. In an embodiment, the first pixel circuit portion PXC1, the second pixel circuit portion PXC2, and the third pixel circuit portion PXC3 may each be repeatedly disposed in a second direction DR2. An arrangement direction of the first pixel circuit portion PXC1, the second pixel circuit portion PXC2, and the third pixel circuit portion PXC3, according to embodiments of the disclosure, may not necessarily be limited thereto.

The first pixel electrode PE1, the second pixel electrode PE2, and the third pixel electrode PE3 may be disposed on the via insulating layer VIA. In an embodiment, the first pixel electrode PE1, the second pixel electrode PE2, and the third pixel electrode PE3 may be disposed on the first pixel circuit portion PXC1, the second pixel circuit portion PXC2, and the third pixel circuit portion PXC3, respectively. In an embodiment, the first pixel electrode PE1, the second pixel electrode PE2, and the third pixel electrode PE3 may be spaced apart from each other in a plan view. In the disclosure, at least one of the first pixel electrode PE1, the second pixel electrode PE2, and the third pixel electrode PE3 may be referred to as a pixel electrode.

In an embodiment, the first pixel electrode PE1, the second pixel electrode PE2, and the third pixel electrode PE3 may be disposed in a same layer. For example, the first pixel electrode PE1, the second pixel electrode PE2, and the third pixel electrode PE3 may include a same material and may be formed by a same process. For example, each of the first pixel electrode PE1, the second pixel electrode PE2, and the third pixel electrode PE3 may include a metal, an alloy, a conductive metal oxide, a conductive metal nitride, a transparent conductive material, and the like.

In an embodiment, the first pixel electrode PE1 may be electrically connected to the first pixel circuit portion PXC1. In an embodiment, the second pixel electrode PE2 may be electrically connected to the second pixel circuit portion PXC2. In an embodiment, the third pixel electrode PE3 may be electrically connected to the third pixel circuit portion PXC3.

In an embodiment, in a plan view, a size of the first pixel electrode PE1 and a size of the second pixel electrode PE2 may be substantially a same. In an embodiment, in a plan view, a size of the third pixel electrode PE3 may be greater than a size of each of the first pixel electrode PE1 and the second pixel electrode PE2. size or shape of each of the first pixel electrode PE1, the second pixel electrode PE2, and the third pixel electrode PE3, according to embodiments of the disclosure, may not necessarily be limited thereto.

The pixel defining layer PDL may be disposed on the via insulating layer VIA. The pixel defining layer PDL may partially cover the first pixel electrode PE1. In addition, a hole for exposing at least a portion of the first pixel electrode PE1 may be defined in the pixel defining layer PDL. For example, the hole defined in the pixel defining layer PDL may expose a central portion of the first pixel electrode PE1, and the pixel defining layer PDL may cover an edge portion of the first pixel electrode PE1. In an embodiment, the pixel defining layer PDL may include an organic insulating material such as polyimide. In FIG. 6, a case that pixel defining layer PDL partially exposes the first pixel electrode PE1 is illustrated, and the pixel defining layer PDL, according to embodiments of the disclosure, may not necessarily be limited thereto, and the pixel defining layer PDL may partially cover each of the second pixel electrode PE2 and the third pixel electrode PE3.

The first light-emitting layer EML1 may be disposed on the first pixel electrode PE1. In an embodiment, in a plan view, the first light-emitting layer EML1 may overlap the first pixel electrode PE1. For example, in a plan view, the first light-emitting layer EML1 may be disposed inside a boundary of the first pixel electrode PE1.

The second light-emitting layer EML2 may be disposed on the second pixel electrode PE2. In an embodiment, in a plan view, the second light-emitting layer EML2 may overlap the second pixel electrode PE2. For example, in a plan view, the second light-emitting layer EML2 may be disposed inside a boundary of the second pixel electrode PE2.

The third light-emitting layer EML3 may be disposed on the third pixel electrode PE3. In an embodiment, in a plan view, the third light-emitting layer EML3 may overlap the third pixel electrode PE3. For example, in a plan view, the third light-emitting layer EML3 may be disposed inside a boundary of the third pixel electrode PE3.

In an embodiment, in a plan view, the first light-emitting layer EML1, the second light-emitting layer EML2, and the third light-emitting layer EML3 may be spaced apart from each other. In an embodiment, the first light-emitting layer EML1, the second light-emitting layer EML2, and the third light-emitting layer EML3 may be disposed in a same layer. For example, the first light-emitting layer EML1, the second light-emitting layer EML2, and the third light-emitting layer EML3 may include a same material and may be formed through a same process.

In an embodiment, the first light-emitting layer EML1, the second light-emitting layer EML2, and the third light-emitting layer EML3 may include an organic light-emitting material. The organic light-emitting material may include a low molecular weight organic compound or a high molecular weight organic compound. The present disclosure may not necessarily be limited thereto, and the first light-emitting layer EML1, the second light-emitting layer EML2, and the third light-emitting layer EML3 may also include a material such as a quantum dot.

The common electrode CE may be disposed on the first light-emitting layer EML1, the second light-emitting layer EML2, and the third light-emitting layer EML3. The common electrode CE may cover the first light-emitting layer EML1, the second light-emitting layer EML2, the third light-emitting layer EML3, and the pixel defining layer PDL. In an embodiment, the common electrode CE may include a metal, an alloy, a conductive metal oxide, a conductive metal nitride, a transparent conductive material, and the like. For example, the common electrode CE may include aluminum (Al), platinum (Pt), silver, magnesium (Mg), gold (Au), chromium (Cr), tungsten (W), titanium (Ti), and the like. These may be used alone or in combination with each other. In the disclosure, at least one of the first light-emitting element EE1, the second light-emitting element EE2, and the third light-emitting element EE3 may be referred to as a light-emitting element.

The first inorganic encapsulation layer IL1 may be disposed on the common electrode CE. The first inorganic encapsulation layer IL1 may cover the light-emitting element layer LEL. The first inorganic encapsulation layer IL1 may have a substantially uniform thickness along the profile of the common electrode CE. In an embodiment, the first inorganic encapsulation layer IL1 may include an inorganic insulating material. For example, the inorganic insulating material may include silicon nitride, silicon oxide, silicon oxynitride, and the like. These may be used alone or in combination with each other.

The organic encapsulation layer OL may be disposed on the first inorganic encapsulation layer IL1. The organic encapsulation layer OL may have a substantially flat upper surface without forming a step around the first inorganic encapsulation layer IL1. In an embodiment, the organic encapsulation layer OL may include an organic insulating material. For example, the organic insulating material may include acrylic resin, epoxy resin, polyimide, polyethylene, and the like. These may be used alone or in combination with each other.

The second inorganic encapsulation layer IL2 may be disposed on the organic encapsulation layer OL. The second inorganic encapsulation layer IL2 may have a substantially uniform thickness and a substantially flat upper surface. In an embodiment, the second inorganic encapsulation layer IL2 may include an inorganic insulating material. For example, the inorganic insulating material may include silicon nitride, silicon oxide, silicon oxynitride, and the like. These may be used alone or in combination with each other. The encapsulation layer ENC may seal the first display area DA1 and the second display area (e.g., the second display area DA2 of FIG. 1) of the display panel DP to protect the first, second, and third light-emitting elements EE1, EE2, and EE3 from external impurities.

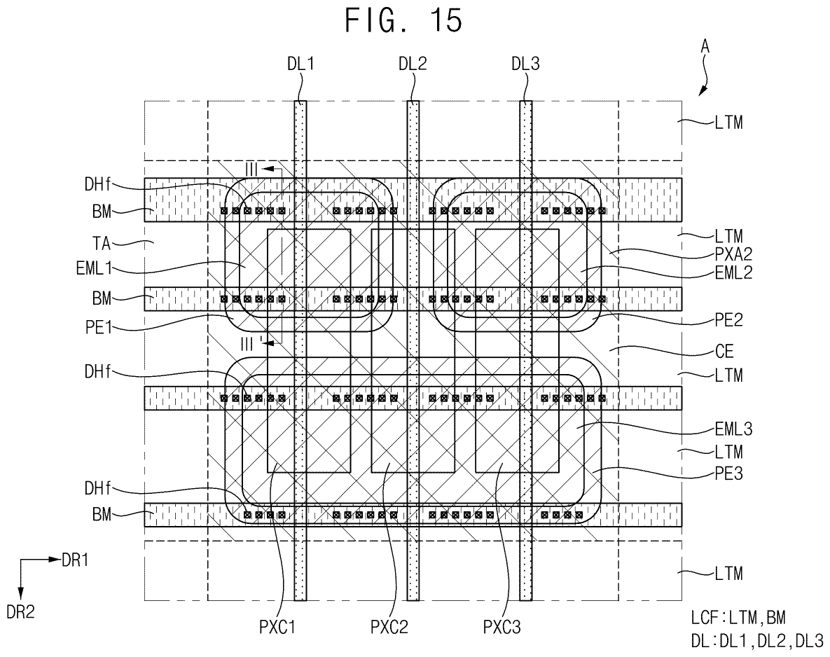

The light control film LCF may control an angle (e.g., a viewing angle) at which light emitted from the light-emitting element layer LEL is visible to a user. The light control film LCF may include a plurality of light blockers (e.g., a plurality of light blockers BM of FIG. 15) and a plurality of light-transmitting films (e.g., a plurality of light-transmitting films LTM of FIG. 15).

The plurality of light blockers and the plurality of light-transmitting films may be disposed in the first display area DA1 and the second display area DA2. The plurality of light blockers and the plurality of light-transmitting films may be repeatedly disposed in the light control film LCF. For example, the light blockers and the plurality of light-transmitting films may be alternately disposed along a second direction DR2. An arrangement direction of the light blockers and the plurality of light-transmitting films, according to embodiments of the disclosure, may not necessarily be limited thereto.

The functional module FM may be disposed corresponding to the second display area DA2. In an embodiment, examples of the functional module FM may include a camera module, a face recognition sensor module, a pupil recognition sensor module, an acceleration sensor module (e.g., an accelerometer), a proximity sensor module, an infrared sensor module, and an illuminance sensor module and the like. The camera module may be a module that captures (or recognizes) an image of an object disposed on a front surface of the display device. The face recognition sensor module may be a module that detects a user's face. The pupil recognition sensor module may be a module that detects a user's pupil. The acceleration sensor module and the geomagnetic sensor module may be modules that determine a movement of the display device. The proximity sensor module and the infrared sensor module may be modules that detect proximity of a front surface of the display device. The illuminance sensor module may be a module that measures a level of external brightness.

Components included in the display device DD, according to embodiments of the present disclosure, may not necessarily be limited to the substrate SUB, the display panel DP, the light control film LCF, and the functional module FM, and the display device DD may further include other components in addition to the substrate SUB, the display panel DP, the light control film LCF, and the functional module FM.

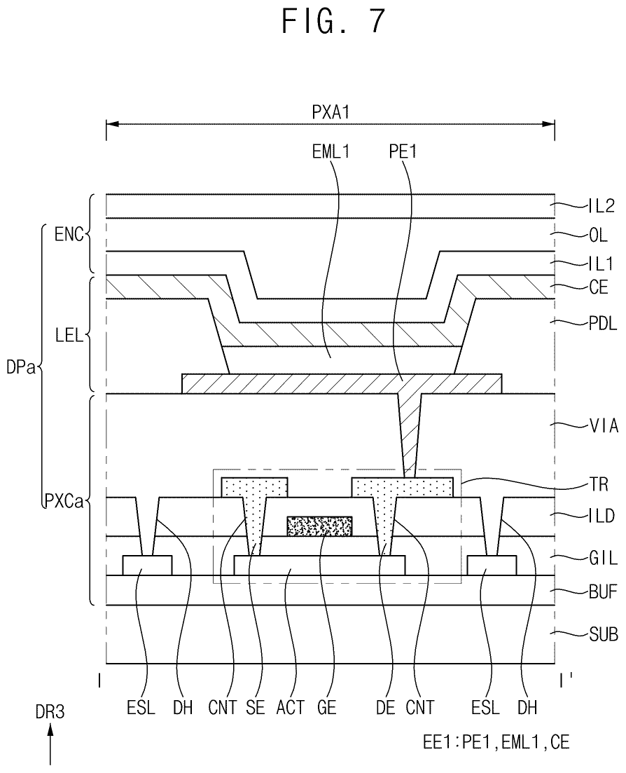

FIG. 7 is a cross-sectional view illustrating an example of a cross-section taken along line I-I′ of FIG. 5.

A cross-section of the substrate SUB and a display panel DPa described with reference to FIG. 7 may be substantially a same as or similar to the cross-section of the substrate SUB and the display panel DP described with reference to FIG. 6, except that the cross-section reference to FIG. 7 further includes an etch-stop layer ESL and in the cross-section reference to FIG. 7, a dummy hole DH is defined. Hereinafter, any content overlapping with the content described with reference to FIG. 6 may be omitted or briefly described. In the disclosure, the dummy hole DH disposed in the first display area DA1 may be referred to as a second dummy hole.

Referring to FIG. 7, the display device DD may include a display panel DPa. The pixel circuit layer PXCa of the display panel DPa may further include an etch stop layer ESL. In an embodiment, the etch stop layer ESL may be disposed in a same layer as the active layer ACT. For example, the etch stop layer ESL may include a same material as the active layer ACT and may be formed through a same process as the active layer ACT. In the disclosure, the etch stop layer ESL disposed in the first display area DA1 may be referred to as the second etch stop layer.

A dummy hole DH penetrating the gate insulating layer GIL and the interlayer insulating layer ILD in a thickness direction (e.g., the third direction DR3) may be defined. The dummy hole DH may expose an upper surface of the etch stop layer ESL. In an embodiment, the via insulating layer VIA may fill the dummy hole DH. For example, the via insulating layer VIA may fill the dummy hole DH and may cover the upper surface of the etch stop layer ESL. In embodiments of the disclosure, the interlayer arrangement of the etch stop layer ESL, a number of layers penetrated by the dummy hole DH, and the shape, size, and number of the dummy holes DH may not necessarily be limited thereto.

The dummy hole DH may be formed through a same process as the contact hole CNT. For example, before forming the source electrode SE and the drain electrode DE on the interlayer insulating layer ILD, the contact hole CNT and the dummy hole DH may be formed by removing portions of the etch stop layer ESL and the interlayer insulating layer ILD. In an embodiment, a plurality of dummy holes DH may be disposed in the first display area DA1.

In an embodiment, in a plan view, the size of the dummy hole DH disposed in the first display area DA1 may be greater than the size of the contact hole CNT. In an embodiment, in a plan view, the size of the dummy hole DH disposed in the first display area DA1 may be smaller than the size of the contact hole CNT. In still an embodiment, in a plan view, the size of the dummy hole DH disposed in the first display area DA1 may be substantially a same as the size of the contact hole CNT.

In an embodiment, in a plan view, the dummy hole DH may be disposed inside the first, second, and third pixel circuit portions (e.g., the first, second, and third pixel circuit portions PXC1, PXC2, and PXC3 of FIG. 5), and may not overlap with conductive lines (e.g., the light-emitting lines EL, scan lines SL, and data lines DL of FIG. 1) and electrodes (e.g., the gate electrode GE, source electrode SE, and drain electrode DE).

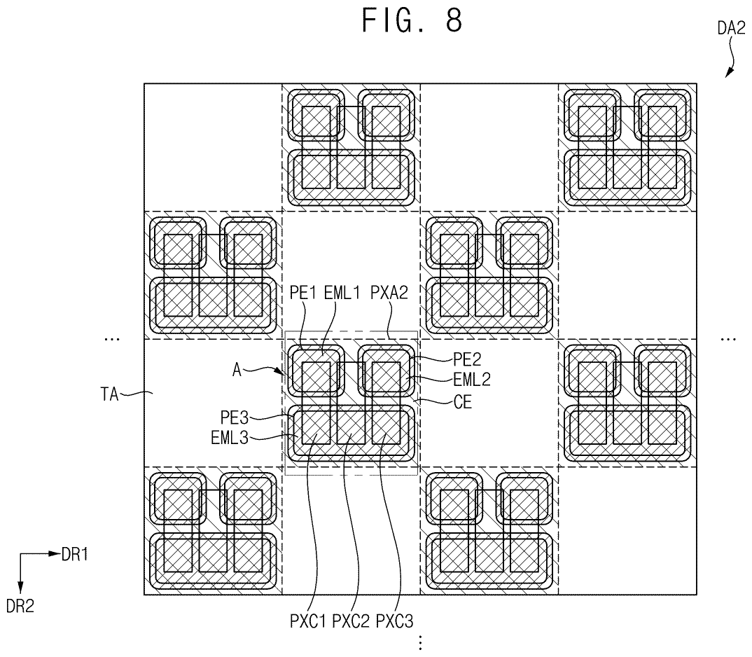

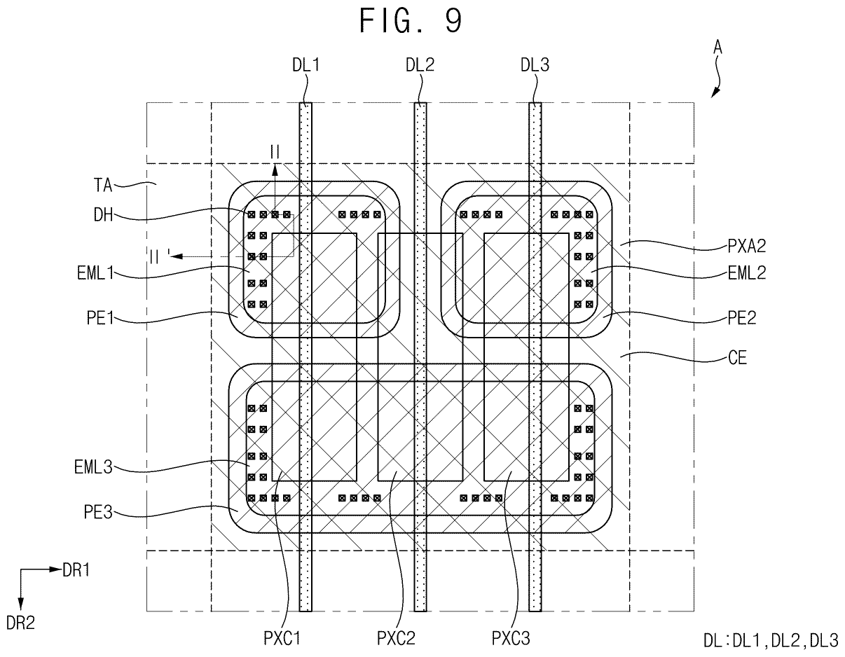

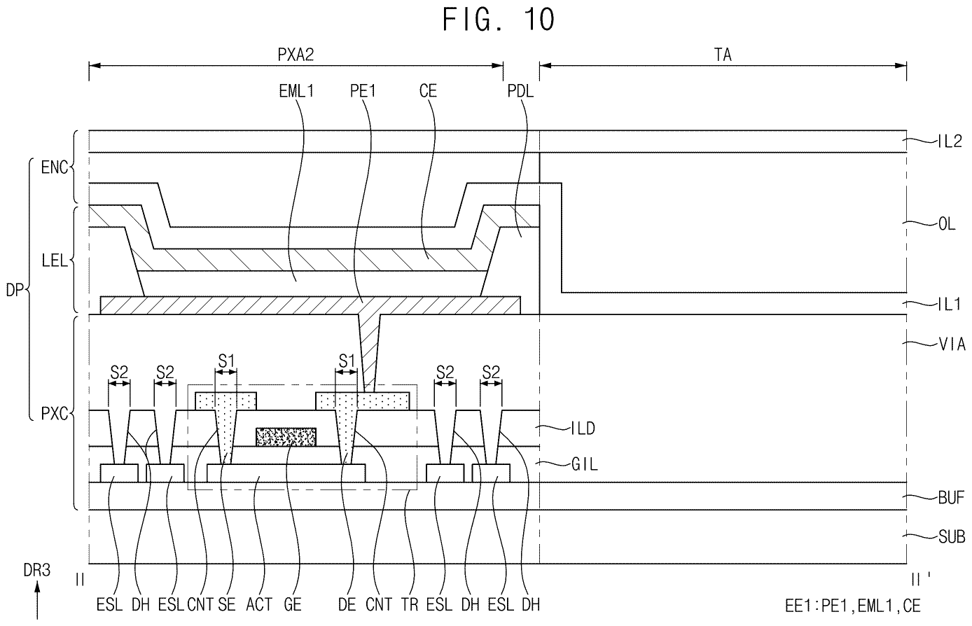

FIG. 8 is a plan view illustrating a second display area of the display device of FIG. 2. FIG. 9 is a plan view illustrating an example in which an area A of FIG. 8 is enlarged. FIG. 10 is a cross-sectional view illustrating an example of a cross-section taken along line II-II′ of FIG. 9.

A second pixel area PXA2, which will be described with reference to FIG. 8, may be substantially a same as or similar to the first pixel area PXA1 described with reference to FIG. 5. A structure of the display panel DP in the second pixel area PXA2, described with reference to FIG. 10, may be substantially a same as or similar to a structure of the display panel DP in the first pixel area PXA1 described with reference to FIG. 6, except that the dummy hole DH is defined and the etch stop layer ESL is further included. In addition, the dummy hole DH described with reference to FIG. 8 may be substantially a same as or similar to the dummy hole DH described with reference to FIG. 7. Hereinafter, to the extent that an element is not described in detail with respect to this figure, it may be understood that the element is at least similar to a corresponding element that has been described elsewhere within the present disclosure, such as with reference to FIGS. 5, 6, and 7.

Referring to FIGS. 8, 9, and 10, the second display area DA2 may include a second pixel area PXA2 and a transmission area TA. The transmission area TA may be adjacent to the second pixel area PXA2. For example, the second pixel area PXA2 and the transmission area TA may be alternately disposed in the second display area DA2 along the first direction DR1 and the second direction DR2.

The transistor TR may be disposed in the second pixel area PXA2. The etch stop layer ESL may be disposed in the second pixel area PXA2. In an embodiment, the etch stop layer ESL may be disposed in a same layer as the active layer ACT. In the disclosure, the transistor TR disposed in the second pixel area PXA2 may be referred to as the first transistor or simply as a transistor. The etch stop layer ESL disposed in the second pixel area PXA2 may be referred to as the first etch stop layer or simply as an etch stop layer.

The dummy hole DH penetrating the gate insulating layer GIL and the interlayer insulating layer ILD in a thickness direction (e.g., the third direction DR3) may be disposed in the second pixel area PXA2. In an embodiment, a plurality of dummy holes DH may be disposed in the second display area DA2. In the disclosure, the dummy hole DH disposed in the second pixel area PXA2 may be referred to as the first dummy hole. In the disclosure, the gate insulating layer GIL and the interlayer insulating layer ILD may be referred to as an insulator.

The dummy hole DH may expose an upper surface of the etch stop layer ESL. For example, the etch stop layer ESL may serve as a layer that prevents the buffer layer BUF from being etched in a thickness direction (e.g., the third direction DR3) while the dummy hole DH is formed through an etching process. In an embodiment, the via insulating layer VIA may fill the dummy hole DH.

In an embodiment, in a plan view, a size S2 of the dummy hole DH may be substantially a same as a size S1 of the contact hole CNT. In the embodiments of the disclosure, the sizes S1 and S2 of the contact hole CNT and the dummy hole DH in the plan view may not necessarily be limited thereto.

In an embodiment, in a plan view, the dummy hole DH may overlap the first pixel electrode PE1. For example, in a plan view, the dummy hole DH may be disposed inside the boundary of the first pixel electrode PE1.

In an embodiment, in a plan view, the dummy hole DH may overlap the second pixel electrode PE2. For example, in a plan view, the dummy hole DH may be disposed inside the boundary of the second pixel electrode PE2.

In an embodiment, in a plan view, the dummy hole DH may overlap the third pixel electrode PE3. For example, in a plan view, the dummy hole DH may be disposed inside the boundary of the third pixel electrode PE3.

In an embodiment, in a plan view, the dummy hole DH may be disposed inside a boundary of the first light-emitting layer EML1. In an embodiment, in a plan view, the dummy hole DH may be disposed inside a boundary of the second light-emitting layer EML2. In an embodiment, in a plan view, the dummy hole DH may be disposed inside a boundary of the third light-emitting layer EML3. In the embodiments of the disclosure, a location of the dummy hole DH may not necessarily be limited thereto. For example, in a plan view, the dummy hole DH may be disposed inside the boundary of the first pixel electrode PE1 and outside the boundary of the first light-emitting layer EML1. For example, in a plan view, the dummy hole DH may be disposed inside the boundary of the second pixel electrode PE2 and outside the boundary of the second light-emitting layer EML2. For example, in a plan view, the dummy hole DH may be disposed inside the boundary of the third pixel electrode PE3 and outside the boundary of the third light-emitting layer EML3.

In an embodiment, in a plan view, the dummy hole DH may be spaced apart from each of the first, second, and third data lines DL1, DL2, and DL3. In an embodiment, in a plan view, the dummy hole DH may be spaced apart from each of a plurality of scan lines to which scan signals (e.g., the gate write signal GW, the gate compensation signal GC, the gate initialization signal GI, and the bypass signal EB in FIG. 3) are applied. In an embodiment, in a plan view, the dummy hole DH may be spaced apart from each of a plurality of light-emitting lines to which light-emitting signals (e.g., the light-emitting signal EM in FIG. 3) are applied.

In an embodiment, a number of dummy holes DH disposed in the second display area DA2 may be greater than a number of dummy holes DH disposed in the first display area (e.g., the first display area DA1 of FIG. 6). For example, the dummy holes DH may be disposed only in the second display area DA2, and not in the first display area. As an example, a number of dummy holes DH disposed in the second display area DA2 may be greater than a number of dummy holes DH disposed in the first display area.

The transmission area TA may be an area through which light is transmitted. For example, external light may be incident on a functional module (e.g., the functional module FM of FIG. 4) through the transmission area TA. Accordingly, the functional module may receive the external light.

In the transmission area TA, the substrate SUB, the buffer layer BUF, the via insulating layer VIA, the first inorganic encapsulation layer IL1, the organic encapsulation layer OL, and the second inorganic encapsulation layer IL2 may be disposed. For example, in the transmission area TA, the substrate SUB, the buffer layer BUF, the via insulating layer VIA, the first inorganic encapsulation layer IL1, the organic encapsulation layer OL, and the second inorganic encapsulation layer IL2 may be sequentially stacked along a third direction DR3.

The transmission area TA may not include a transistor TR. In addition, the transmission area TA may not include conductive layers (e.g., the gate electrode GE, the source electrode SE, the drain electrode DE, first, the second, and third pixel electrodes PE1, PE2, PE3, and the common electrode CE). In an embodiment, the dummy hole DH may be spaced apart from the transmission area TA in a plan view. For example, the dummy hole DH may not be disposed in the transmission area TA.

As described above, referring further to FIGS. 1, 2, 3, 4, 5, 6, and 7, in the display device DD, according to an embodiment of the present disclosure, in the second pixel area PXA2 included in the second display area DA2 where the functional module FM is disposed, the dummy hole DH may expose the upper surface of the etch stop layer ESL and may be spaced apart from each of the lines (e.g., the plurality of scan lines SL, the plurality of light-emitting lines EL, and the plurality of data lines DL) to which electrical signals are applied in a plan view. Accordingly, the etch stop layer ESL may block a path through which hydrogen released from insulating layers disposed under the etch stop layer ESL is flow into the active layer ACT, thereby reducing a problem in which the threshold voltage of a transistor (e.g., any of the first, second, third, fourth, fifth, sixth, and seventh pixel transistors PT1, PT2, PT3, PT4, PT5, PT6, and PT7) for operating the pixel PX is formed unstably, or the problem in which the hysteresis characteristic may be weakened. Therefore, the display quality of the display device DD may be increased.

In addition, a number of dummy holes DH disposed in the second display area DA2 may be greater than a number of dummy holes DH disposed in the first display area DA1. Accordingly, an instability in threshold voltage formation of the transistor for operating the pixel PX or a degradation in hysteresis characteristics may be further reduced, thereby further increasing the display quality of the display device DD.

In an embodiment, in the second display area DA2, the dummy hole DH may overlap with the first, second, and third pixel electrodes PXE1, PXE2, and PXE3 in a plan view. For example, in the second display area DA2, the dummy hole DH may be disposed inside the boundary of each of the first, second, and third pixel electrodes PXE1, PXE2, and PXE3 in a plan view. Accordingly, since the first, second, and third pixel electrodes PXE1, PXE2, and PXE3, which absorb or reflect external light, are disposed above the dummy hole DH, a phenomenon in which the amount of external light received by the functional module FM is reduced due to a curvature formed in the insulator by the dummy hole DH may be prevented.

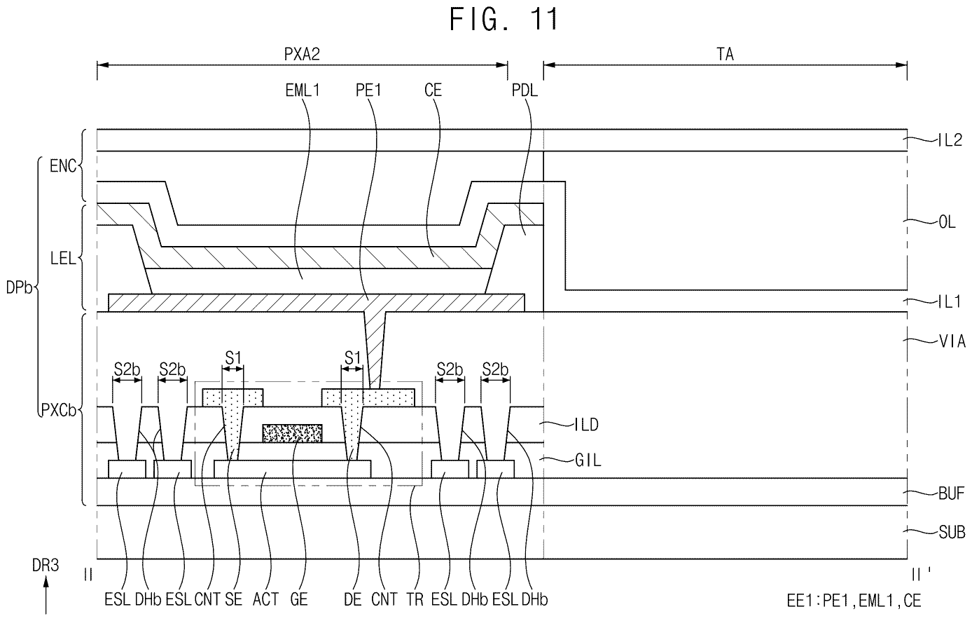

FIG. 11 is a cross-sectional view illustrating an example of a cross-section taken along line II-II′ of FIG. 9. A display panel DPb described with reference to FIG. 11 and the display panel DP described with reference to FIG. 10 may be substantially a same or similar, except that a dummy hole DHb of FIG. 11 and the dummy hole DH of FIG. 10 are different in size in a plan view. Hereinafter, to the extent that an element is not described in detail with respect to this figure, it may be understood that the element is at least similar to a corresponding element that has been described elsewhere within the present disclosure with reference to FIG. 10.

Referring to FIGS. 9 and 11, a dummy hole DHb may be defined in a pixel circuit layer PXCb of a display panel DPb. In an embodiment, in a plan view, a size S2b of the dummy hole DHb may be greater than the size S1 of the contact hole CNT. For example, in a plan view, the length of the dummy hole DHb in the first direction DR1 may be greater than the length of the contact hole CNT in the first direction DR1. A length of the dummy hole DHb in a second direction DR2 may be greater than a length of the contact hole CNT in the second direction DR2.

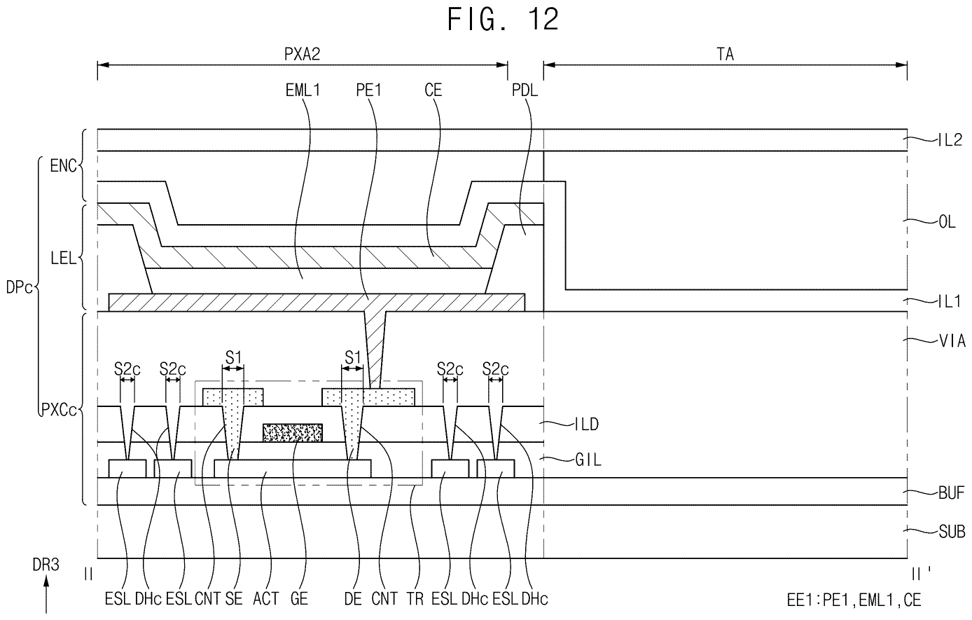

FIG. 12 is a cross-sectional view illustrating still an example of a cross-section taken along line II-II′ of FIG. 9. A display panel DPc described with reference to FIG. 12 and the display panel DP described with reference to FIG. 10 may be substantially a same or similar, except that a dummy hole DHc of FIG. 12 and the dummy hole DH of FIG. 10 are different in size in a plan view. Hereinafter, to the extent that an element is not described in detail with respect to this figure, it may be understood that the element is at least similar to a corresponding element that has been described elsewhere within the present disclosure with reference to FIG. 10.

Referring to FIGS. 9 and 12, a dummy hole DHc may be defined in a pixel circuit layer PXCc of a display panel DPc. In an embodiment, in a plan view, a size S2c of the dummy hole DHc may be greater than the size S1 of the contact hole CNT. For example, in a plan view, a length of the dummy hole DHc in the first direction DR1 may be greater than a length of the contact hole CNT in the first direction DR1. A length of the dummy hole DHc in the second direction DR2 may be greater than a length of the contact hole CNT in the second direction DR2.

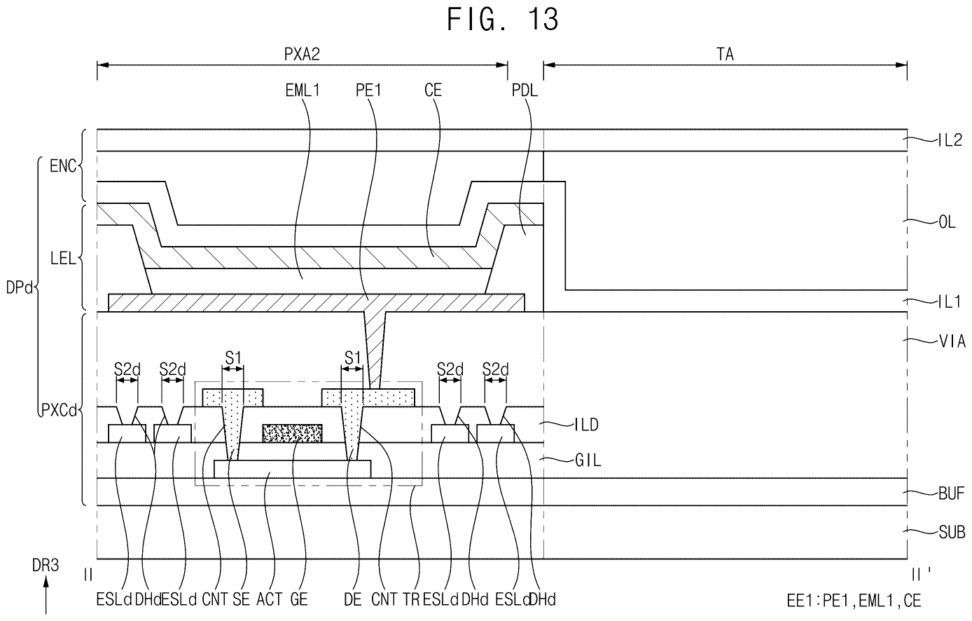

FIG. 13 is a cross-sectional view illustrating an example of a cross-section taken along line II-II′ of FIG. 9. A display panel DPd described with reference to FIG. 13 and the display panel DP described with reference to FIG. 10 may be substantially a same or similar, except that an arrangement and size of an etch stop layer ESLd and a dummy hole DHd of FIG. 13 are different from those of the etch stop layer ESL and the dummy hole DH of FIG. 10. Hereinafter, to the extent that an element is not described in detail with respect to this figure, it may be understood that the element is at least similar to a corresponding element that has been described elsewhere within the present disclosure with reference to FIG. 10.

Referring to FIGS. 9 and 13, the pixel circuit layer PXCb of the display panel DPb may include an etch stop layer ESLd, and a dummy hole DHd may be defined in the pixel circuit layer PXCb. In an embodiment, the etch stop layer ESLd may be disposed in a same layer as the gate electrode GE. For example, the etch stop layer ESLd may include a same material as the gate electrode GE and may be formed through a same process.

The dummy hole DHd may penetrate the interlayer insulating layer ILD in a thickness direction (e.g., a third direction DR3). The dummy hole DHd may expose an upper surface of the etch stop layer ESLd. In an embodiment, a length of the dummy hole DHd in the third direction DR3 may be smaller than a length of the contact hole CNT in the third direction DR3. In the disclosure, the interlayer insulating layer ILD may be referred to as an insulator.

The dummy hole DHd may be formed through a same process as the contact hole CNT. For example, before the source electrode SE and the drain electrode DE are formed on the interlayer insulating layer ILD, the dummy hole DHd may be formed by removing a portion of the interlayer insulating layer ILD. The etch stop layer ESLd may be a layer that prevents etching in the thickness direction (e.g., the third direction DR3) of the gate insulating layer GIL during the etching process for forming the dummy hole DHd.

In an embodiment, in a plan view, a size S2d of the dummy hole DHd may be substantially a same as the size S1 of the contact hole CNT. In an embodiment, in a plan view, a size S2d of the dummy hole DHd may be different from the size S1 of the contact hole CNT. For example, a size S2d of the dummy hole DHd may be greater than a size S1 of the contact hole CNT. In an example, a size S2d of the dummy hole DHd may be smaller than a size S1 of the contact hole CNT.

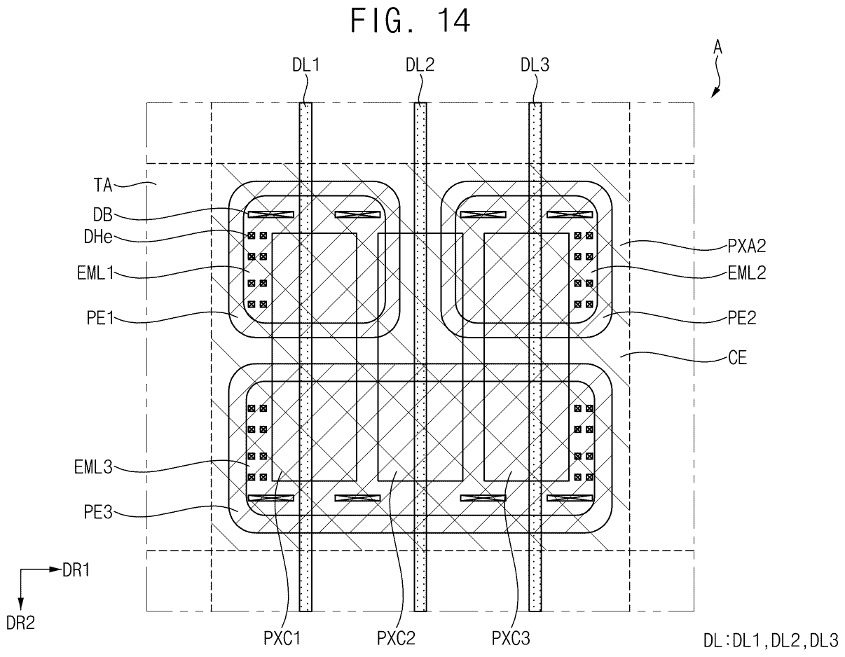

FIG. 14 is a plan view illustrating an example in which area A of FIG. 8 is enlarged. The display device with reference to FIG. 14 may be substantially a same as or similar to the display device described with reference to FIG. 9, except for a bar-shaped of a dummy hole DB and a dummy hole DHe. Hereinafter, to the extent that an element is not described in detail with respect to this figure, it may be understood that the element is at least similar to a corresponding element that has been described elsewhere within the present disclosure with reference to FIG. 9.

Referring to FIG. 14, a bar-shaped dummy hole DB and a dummy hole DHe may be disposed in the second display area DA2. In the disclosure, the bar-shaped dummy hole DB may be referred to as a fourth dummy hole.

In an embodiment, in a plan view, a size of the bar-shaped dummy hole DB may be greater than a size of the dummy hole DHe.

In an embodiment, the bar-shaped dummy hole DB may be extended in one direction. For example, the bar-shaped dummy hole DB may be extended in the first direction DR1.

In an embodiment, a length of the bar-shaped dummy hole DB in the first direction DR1 may be greater than a length in the second direction DR2. The size and shape of the bar-shaped dummy hole DB according to embodiments of the disclosure may not necessarily be limited thereto. For example, the length of the bar-shaped dummy hole DB in the first direction DR1 may be substantially a same as or smaller than the length in the second direction DR2.

In an embodiment, the bar-shaped dummy hole DB may be spaced apart from each of the first, second, and third data lines DL1, DL2, and DL3. In an embodiment, one of the first, second, and third data lines DL1, DL2, and DL3 may be disposed between two bar-shaped dummy holes.

For example, in a plan view, the first data line DL1 may be disposed between two bar-shaped dummy holes adjacent to the first data line DL1. Similarly, in a plan view, the second data line DL2 may be disposed between two bar-shaped dummy holes adjacent to the second data line DL2. Likewise, the third data line DL3 may be disposed between two bar-shaped dummy holes adjacent to the third data line DL3.

In an embodiment, the bar-shaped dummy hole DB may overlap, in a plan view, each of the first, second, and third pixel electrodes PE1, PE2, and PE3. For example, the bar-shaped dummy hole DB may be disposed inside boundaries of each of the first, second, and third pixel electrodes PE1, PE2, and PE3. In an embodiment, the dummy hole DHe may also overlap, in a plan view, each of the first, second, and third pixel electrodes PE1, PE2, and PE3. For example, the dummy hole DHe may be disposed inside the boundaries of each of the first to third pixel electrodes PE1, PE2, and PE3.

Referring further to FIG. 6, in an embodiment, the bar-shaped dummy hole DB may penetrate the gate insulating layer GIL and the interlayer insulating layer ILD in the thickness direction (e.g., the third direction DR3). In an embodiment, the bar-shaped dummy hole DB may penetrate only the interlayer insulating layer ILD in the thickness direction (e.g., the third direction DR3).

In an embodiment, in a plan view, a size of the etch stop layer exposed by the bar-shaped dummy hole DB may be greater than a size of the etch stop layer exposed by the dummy hole DHe. For example, the size of the etch stop layer exposed by the bar-shaped dummy hole DB in the plan view may correspond to the size of the bar-shaped dummy hole DB.

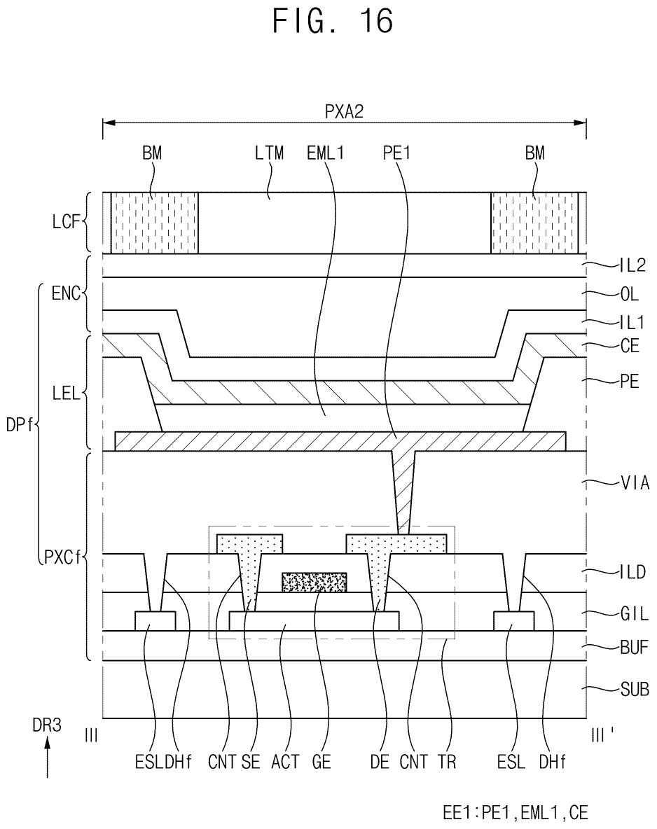

FIG. 15 is a plan view illustrating an example in which area A of FIG. 8 is enlarged. FIG. 16 is a cross-sectional view illustrating a cross-section taken along line III-III′ of FIG. 15.

A display device described with reference to FIGS. 15 and 16 may be substantially a same as or similar to the display device described with reference to FIGS. 9 and 10, except that an arrangement of a dummy hole DHf in FIGS. 15 and 16 is different from the arrangement of the dummy hole DH in FIG. 10. Hereinafter, to the extent that an element is not described in detail with respect to this figure, it may be understood that the element is at least similar to a corresponding element that has been described elsewhere within the present disclosure referring to FIGS. 9 and 10.

Referring to FIGS. 15 and 16, in the second display area DA2, a dummy hole DHf may be defined in the pixel circuit layer PXCf of the display panel DPf. In an embodiment, in a plan view, the dummy hole DHf may overlap each of the plurality of light blockers BM. For example, in a plan view, the dummy hole DHf may be disposed inside a boundary of each of the plurality of light blockers BM. For example, the dummy hole DHf may overlap each of the plurality of light blockers BM in a plan view. For example, the dummy holes DHf may be repeatedly disposed along the second direction DR2 in which the plurality of light blockers BM extend. The dummy hole DHf may be disposed inside the boundaries of the light blockers BM and may be disposed either inside or outside the boundaries of each of the first to third pixel electrodes PE1, PE2, and PE3. In an embodiment, in a plan view, the dummy hole DHf may be disposed outside the boundaries of each of the plurality of light transmission layers LTM.

In an embodiment, the dummy hole DHf may penetrate the gate insulating layer GIL and the interlayer insulating layer ILD in the thickness direction (e.g., the third direction DR3). For example, the dummy hole DHf may expose an upper surface of the etch stop layer ESL disposed in a same layer as the active layer ACT. The dummy hole DHf according to embodiments of the disclosure may not necessarily be limited thereto and may penetrate the interlayer insulating layer ILD in the thickness direction (e.g., the third direction DR3). For example, the dummy hole DHf may expose an upper surface of the etch stop layer disposed in a same layer as the gate electrode GE.

In an embodiment, in a plan view, the dummy hole DHf may be spaced apart from each of the first, second, and third data lines DL1, DL2, and DL3. In an embodiment, in a plan view, the dummy hole DHf may be spaced apart from each of the plurality of scan lines to which scan signals (e.g., the gate write signal GW, the gate compensation signal GC, the gate initialization signal GI, and the bypass signal EB of FIG. 3) are applied (e.g., the plurality of scan lines SL of FIG. 1). In an embodiment, in a plan view, the dummy hole DHf may be spaced apart from each of the plurality of light-emitting lines to which light-emitting signals (e.g., the light-emitting signal EM of FIG. 3) are applied (e.g., the plurality of light-emitting lines EL of FIG. 1).

In addition, in the second display area DA2, the dummy hole DH may overlap, in a plan view, each of the plurality of light blockers BM. For example, the dummy hole DH may be disposed inside the boundary of each of the plurality of light blockers BM in a plan view. Accordingly, since a plurality of light blockers BM for absorbing external light are disposed above the dummy hole DH, a phenomenon in which the amount of external light received by a functional module (e.g., the functional module FM of FIG. 4) is reduced due to a curvature formed in the insulator by the dummy hole DH may be prevented.

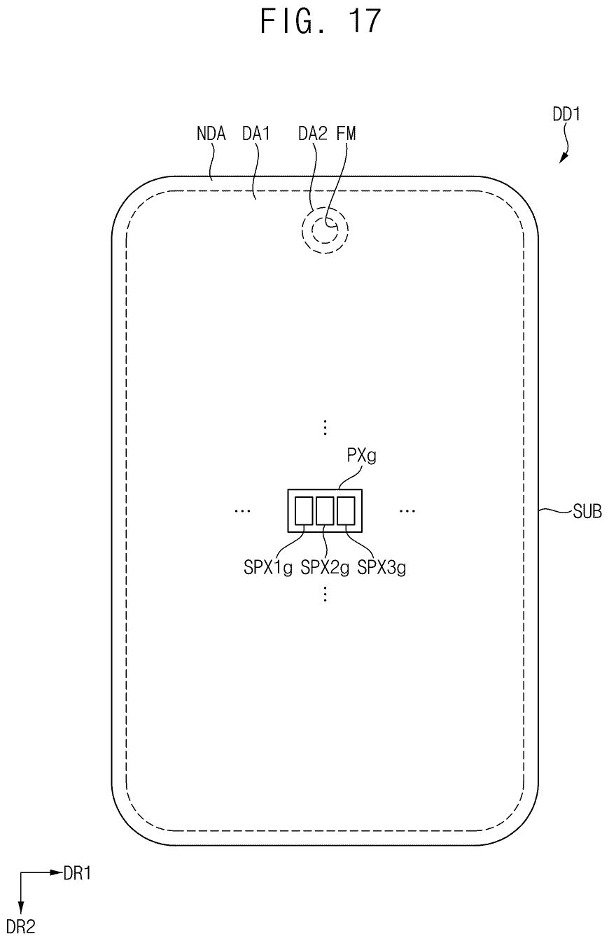

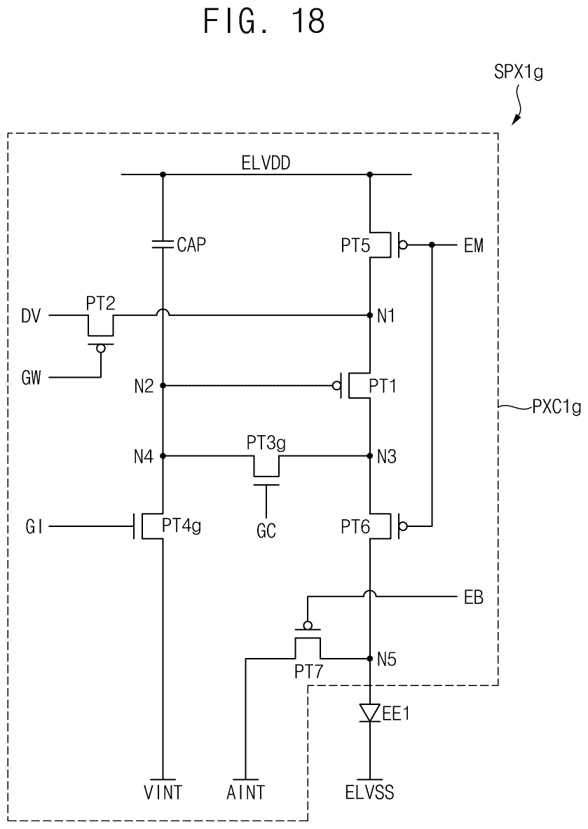

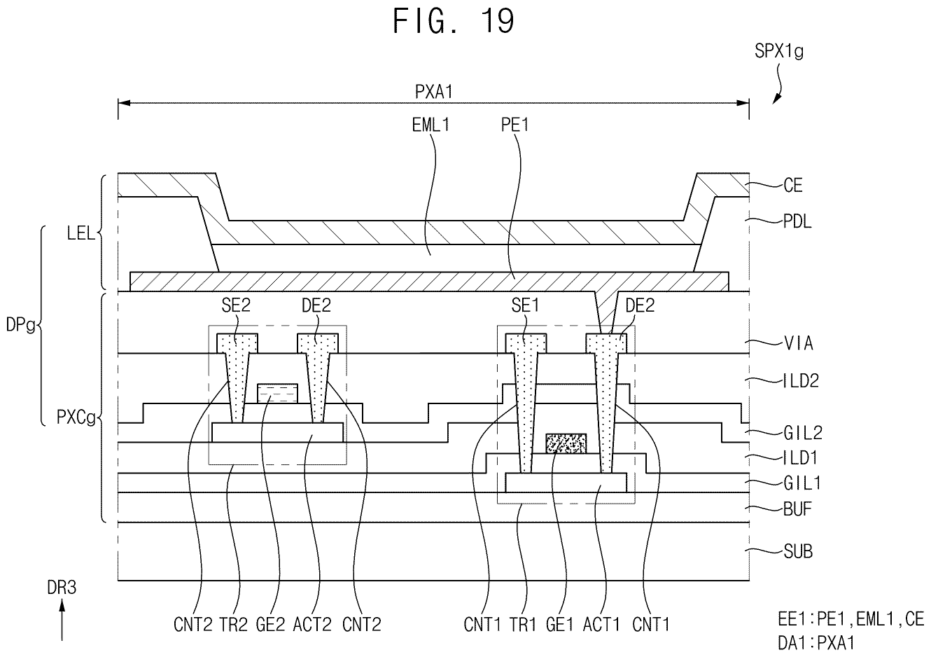

FIG. 17 is a plan view illustrating an example of the display device of FIG. 1. FIG. 18 is a circuit diagram illustrating a first sub-pixel included in the display device of FIG. 17. FIG. 19 is a cross-sectional view illustrating a cross-section in the first display area of the first sub-pixel included in the display device of FIG. 17.

A display device DD1 described with reference to FIGS. 17, 18, and 19 may be substantially a same or similar to the display device DD described with reference to FIGS. 1 to 3 and FIG. 6, except for the stacked structure of the display panel DPg and the types of the third pixel transistor PT3g and the fourth pixel transistor PT4g. Hereinafter, to the extent that an element is not described in detail with respect to this figure, it may be understood that the element is at least similar to a corresponding element that has been described elsewhere within the present disclosure referring FIGS. 1, 2, 3, and 6.

Referring to FIGS. 17, 18, and 19, a display device DD1, according to an embodiment of the present disclosure, may include a pixel PXg. The pixel PXg may include a first sub-pixel SPX1g, a second sub-pixel SPX2g, and a third sub-pixel SPX3g. The first, second, and third sub-pixels SPX1g, SPX2g, and SPX3g may be substantially a same or similar in terms of an arrangement in a plan view and types of light emitted, compared to the first, second, and third sub-pixels SPX1, SPX2, and SPX3 of FIG. 2.

The first sub-pixel SPX1g may include a first pixel circuit portion PXC1g and a first light-emitting element EE1. The first pixel circuit portion PXC1g may include a third pixel transistor PT3g and a fourth pixel transistor PT4g. In an embodiment, each of the third pixel transistor PT3g and the fourth pixel transistor PT4g may be an NMOS transistor. In an embodiment, the gate compensation signal GC and the gate initialization signal GI for turning on the third pixel transistor PT3g and the fourth pixel transistor PT4g may have a positive level. Structures of the second sub-pixel SPX2 and the third sub-pixel SPX3 may be substantially same as a structure of the first sub-pixel SPX1g.

In the first pixel area PXA1 included in the first display area DA1, the display panel DPg may include a pixel circuit layer PXCg and a light-emitting element layer LEL. The pixel circuit layer PXCg may include the buffer layer BUF, a first active layer ACT1, a first gate insulating layer GIL1, a first gate electrode GE1, a first interlayer insulating layer ILD1, a second active layer ACT2, a second gate insulating layer GIL2, a second gate electrode GE2, a second interlayer insulating layer ILD2, a first source electrode SE1, a first drain electrode DE1, a second source electrode SE2, a second drain electrode DE2, and the via insulating layer VIA.

The first active layer ACT1, the first gate electrode GE1, the first source electrode SE1, and the first drain electrode DE1 may define a first transistor TR1. The first transistor TR1 may correspond to one of a pixel transistor among the first, second, fifth, sixth, and seventh pixel transistors PT1, PT2, PT5, PT6, and PT7.

The second active layer ACT2, the second gate electrode GE2, the second source electrode SE2, and the second drain electrode DE2 may define a second transistor TR2. The second transistor TR2 may correspond to one of a pixel transistor among the third and fourth pixel transistors PT3g and PT4g.

The first active layer ACT1 may be disposed on the buffer layer BUF. The first active layer ACT1 may include a source area, a drain area, and a channel area disposed between the source area and the drain area. In an embodiment, the first active layer ACT1 may include amorphous silicon or polycrystalline silicon. However, the first active layer ACT1 according to the embodiments of the disclosure may not necessarily be limited thereto, and the first active layer ACT1 may include an oxide semiconductor.

The first gate insulating layer GIL1 may be disposed on the first active layer ACT1. The first gate electrode GE1 may be disposed on the first gate insulating layer GIL1. The first interlayer insulating layer ILD1 may be disposed on the first gate electrode GE1.

In an embodiment, the first gate insulating layer GIL1 may include an inorganic insulating material. In an embodiment, the first gate electrode GE1 may include a conductive material. In an embodiment, the first interlayer insulating layer ILD1 may include an inorganic insulating material and/or an organic insulating material.

In an embodiment, the first interlayer insulating layer ILD1 may have a multilayer structure. For example, when the first interlayer insulating layer ILD1 has a multilayer structure, an electrode layer defining a storage capacitor together with the first gate electrode GE1 may be further disposed in the first interlayer insulating layer ILD1. The first interlayer insulating layer ILD1 according to the embodiments of the disclosure may not necessarily be limited thereto.

The second active layer ACT2 may be disposed on the first interlayer insulating layer ILD1. The second active layer ACT2 may include a source area, a drain area, and a channel area disposed between the source area and the drain area. In an embodiment, the second active layer ACT2 may include an oxide semiconductor. The second active layer ACT2 according to the embodiments of the disclosure may not necessarily be limited thereto, and the second active layer ACT2 may include amorphous silicon or polycrystalline silicon.

The second gate insulating layer GIL2 may be disposed on the second active layer ACT2. The second gate electrode GE2 may be disposed on the second gate insulating layer GIL2. The second interlayer insulating layer ILD2 may be disposed on the second gate electrode GE2. In an embodiment, the second gate insulating layer GIL2 may include an inorganic insulating material. In an embodiment, the second gate electrode GE2 may include a conductive material. In an embodiment, the second interlayer insulating layer ILD2 may include an inorganic insulating material and/or an organic insulating material. In an embodiment, the second interlayer insulating layer ILD2 may have a single-layer or multilayer structure.

The first source electrode SE1, the first drain electrode DE1, the second source electrode SE2, and the second drain electrode DE2 may be disposed on the second interlayer insulating layer ILD2. In an embodiment, each of the first source electrode SE1 and the first drain electrode DE1 may be electrically connected to the first active layer ACT1. For example, the first source electrode SE1 and the first drain electrode DE1 may respectively contact the source area and the drain area of the first active layer ACT1 through a first contact hole CNT1 penetrating the first gate insulating layer GIL1, the first interlayer insulating layer ILD1, the second gate insulating layer GIL2, and the second interlayer insulating layer ILD2 in a thickness direction (e.g., a third direction DR3).

In an embodiment, each of the second source electrode SE2 and the second drain electrode DE2 may be electrically connected to the second active layer ACT2. For example, the second source electrode SE2 and the second drain electrode DE2 may respectively contact the source area and the drain area of the second active layer ACT2 through a second contact hole CNT2 penetrating the second gate insulating layer GIL2 and the second interlayer insulating layer ILD2 in a thickness direction (e.g., a third direction DR3).

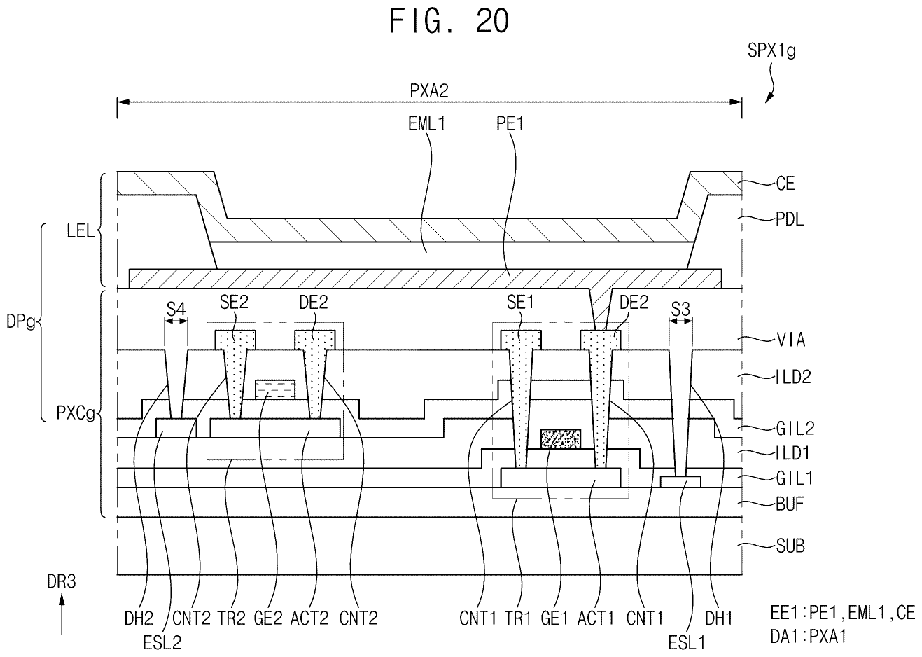

FIG. 20 is a cross-sectional view illustrating an example of a cross-section in the second display area of the first sub-pixel included in the display device of FIG. 17.

Referring to FIGS. 17 and 20, the second display area DA2 may include a second pixel area PXA2 and the transmission area (e.g., the transmission area TA of FIG. 8) as illustrated in FIG. 8. In the second display area DA2, a first dummy hole DH1 and a second dummy hole DH2 may be defined. A first etch stop layer ESL1 and the second etch stop layer ESL2 may be disposed in the second display area DA2. In the disclosure, the second dummy hole DH2 may be referred to as a third dummy hole, and the second etch stop layer ESL2 may be referred to as a third etch stop layer.

In an embodiment, the first etch stop layer ESL1 may be disposed in a same layer as the first active layer ACT1. For example, the first etch stop layer ESL1 may include a same material as the first active layer ACT1 and may be formed through a same process. In an embodiment, the first dummy hole DH1 may expose an upper surface of the first etch stop layer ESL1.

In an embodiment, the first dummy hole DH1 may penetrate in the thickness direction (e.g., in the third direction DR3) through the first gate insulating layer GIL1, the first interlayer insulating layer ILD1, the second gate insulating layer GIL2, and the second interlayer insulating layer ILD2. In an embodiment, the second dummy hole DH2 may penetrate in the thickness direction (e.g., in the third direction DR3) through the second gate insulating layer GIL2 and the second interlayer insulating layer ILD2. In the disclosure, the first gate insulating layer GIL1, the first interlayer insulating layer ILD1, the second gate insulating layer GIL2, and the second interlayer insulating layer ILD2 may be referred to as an insulator.

In an embodiment, the second etch stop layer ESL2 may be disposed in a different layer from the first etch stop layer ESL1. In an embodiment, the second etch stop layer ESL2 may be disposed in a same layer as the second active layer ACT2. For example, the second etch stop layer ESL2 may include a same material as the second active layer ACT2 and may be formed through a same process. In an embodiment, the second dummy hole DH2 may expose an upper surface of the second etch stop layer ESL2.

In an embodiment, in a plan view, a size S3 of the first dummy hole DH1 may be different from a size S4 of the second dummy hole DH2. In an embodiment, in a plan view, the size S3 of the first dummy hole DH1 may be substantially a same as the size S4 of the second dummy hole DH2.

In an embodiment, in a plan view, the size S3 of the first dummy hole DH1 may be different from a size of a first contact hole CNT1. In an embodiment, in a plan view, the size S3 of the first dummy hole DH1 may be substantially a same as the size of the first contact hole CNT1.

In an embodiment, in a plan view, the size S4 of the second dummy hole DH2 may be different from a size of a second contact hole CNT2. In an embodiment, in a plan view, the size S4 of the second dummy hole DH2 may be substantially a same as the size of the second contact hole CNT2.

In an embodiment, in a plan view, each of the first dummy hole DH1 and the second dummy hole DH2 may overlap the first pixel electrode PE1. For example, in a plan view, each of the first dummy hole DH1 and the second dummy hole DH2 may be disposed inside a boundary of the first pixel electrode PE1. Further, in a plan view, the first dummy hole DH1 and the second dummy hole DH2 may overlap the second and third pixel electrodes (e.g., the second and third pixel electrodes PE2 and PE3 of FIG. 8). For example, the first dummy hole DH1 and the second dummy hole DH2 may be disposed inside each of a boundary of the second and third pixel electrodes.

In an embodiment, in a plan view, each of the first dummy hole DH1 and the second dummy hole DH2 may overlap a plurality of light blockers (e.g., the light blockers BM of FIG. 15). For example, each of the first dummy hole DH1 and the second dummy hole DH2 may be disposed inside each of the light blockers.

In FIGS. 19 and 20 the first and second dummy holes DH1 and DH2 are illustrated as disposed only in the second pixel area PXA2, the first and second dummy holes DH1 and DH2, according to embodiments of the disclosure, may not necessarily be limited thereto, and each of the first and second dummy holes DH1 and DH2 may be disposed in the first pixel area PXA1. For example, when each of the first and second dummy holes DH1 and DH2 is disposed in the first pixel area PXA1, the number of the first and second dummy holes DH1 and DH2 disposed in the first pixel area PXA1 may be smaller than the number of the first and second dummy holes DH1 and DH2 disposed in the second pixel area PXA2.

As described above, referring further to FIGS. 18 and 19, in a display device DD1, according to an embodiment of the disclosure, in the second pixel area PXA2 included in the second display area DA2 where a functional module (e.g., the functional module FM of FIG. 4) is disposed, the first and second dummy holes DH1 and DH2 respectively expose upper surfaces of the first and second etch stop layers ESL1 and ESL2 and may be spaced apart from each of the lines to which electrical signals are applied (e.g., a plurality of scan lines SL, a plurality of light-emitting lines EL, and a plurality of data lines DL) in a plan view. Accordingly, the first and second etch stop layers ESL1 and ESL2 may block paths through which hydrogen emitted from insulating layers disposed under the first and second etch stop layers ESL1 and ESL2 is respectively introduced into the first and second active layers ACT1 and ACT2, so that problems such as unstable formation of threshold voltages of transistors (e.g., the first to seventh pixel transistors PT1, PT2, PT3g, PT4g, PT5, PT6, and PT7) for operating a pixel PXg or deterioration of hysteresis characteristics may be reduced. Therefore, display quality of the display device DD1 may be increased.

Further, a number of the first and second dummy holes DH1 and DH2 disposed in the second display area DA2 may be greater than a number of the first and second dummy holes disposed in the first display area DA1. Accordingly, the problem of unstable formation of the threshold voltages of the transistors for operating the pixel PXg or the deterioration of hysteresis characteristics may be further reduced, thereby further increasing the display quality of the display device DD1.

Further, in the second display area DA2, the first and second dummy holes DH1 and DH2 may overlap each of the first pixel electrode PXE1 and the second and third pixel electrodes in a plan view. For example, in the second display area DA2, the first and second dummy holes DH1 and DH2 may be disposed inside boundaries of the first pixel electrode PXE1 and the respective second and third pixel electrodes in a plan view. Accordingly, since the first pixel electrode PXE1 and the second and third pixel electrodes that absorb or reflect external light are disposed over the first and second dummy holes DH1 and DH2, a phenomenon in which external light received by the functional module decreases due to bends formed in an insulator by the dummy holes DH may be prevented.

Further, in the second display area DA2, the first and second dummy holes DH1 and DH2 may overlap each of the plurality of light blockers in a plan view. For example, in the second display area DA2, the first and second dummy holes DH1 and DH2 may be disposed inside a boundary of each of the plurality of light blockers in a plan view. Accordingly, since the plurality of light blockers that absorb external light are disposed above the first and second dummy holes DH1 and DH2, a phenomenon in which external light received by the functional module decreases due to bends formed in an insulator by the dummy holes DH may be prevented.

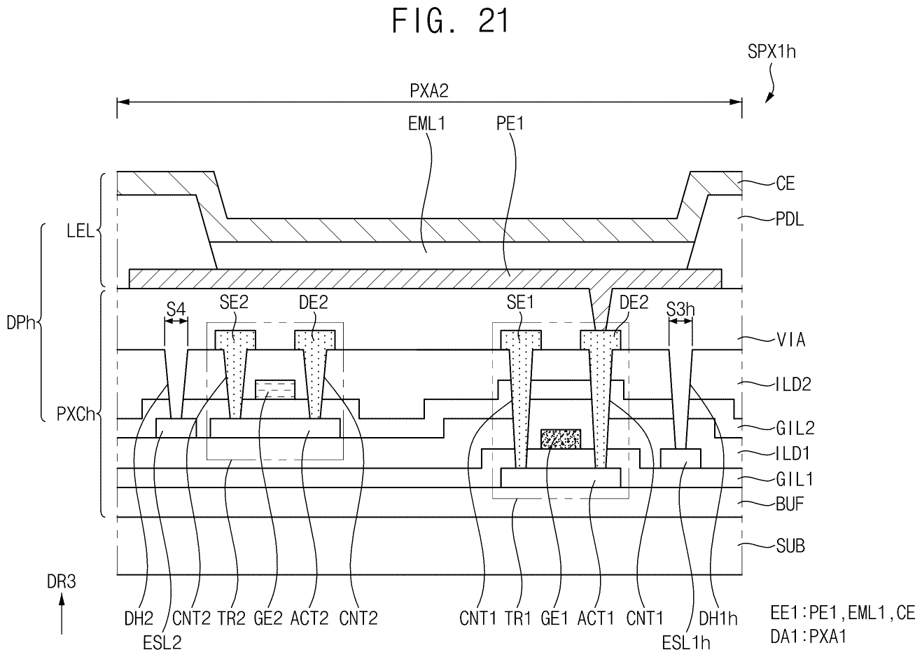

FIG. 21 is a cross-sectional view illustrating an example of a cross-section in the second display area of the first sub-pixel included in the display device of FIG. 17. A display panel DPh described with reference to FIG. 21 and the display panel DPg described with reference to FIG. 20 may be substantially a same or similar to each other, except that an arrangement of a first dummy hole DH1h and a first etch stop layer ESL1h in FIG. 21 is different from an arrangement of a first dummy hole DH1g and a first etch stop layer ESL1g in FIG. 20. Hereinafter, to the extent that an element is not described in detail with respect to this figure, it may be understood that the element is at least similar to a corresponding element that has been described elsewhere within the present disclosure referring to FIG. 20.

Referring to FIG. 21, a pixel circuit layer PXCh of the display panel DPh may include a first etch stop layer ESL1h, and a first dummy hole DH1h may be defined in the pixel circuit layer PXCh. The first etch stop layer ESL1h may be disposed in a same layer as a first gate electrode GE1. For example, the first etch stop layer ESL1h may include a same material as the first gate electrode GE1 and may be formed through a same process. The first dummy hole DH1h may penetrate in the thickness direction (e.g., in a third direction DR3) through a first interlayer insulating layer ILD1, a second gate insulating layer GIL2, and a second interlayer insulating layer ILD2. In the disclosure, the first interlayer insulating layer ILD1, the second gate insulating layer GIL2, and the second interlayer insulating layer ILD2 may be referred to as an insulator.

In an embodiment, in a plan view, a size S3h of the first dummy hole DH1h may be different from a size of a first contact hole CNT1. In an embodiment, in a plan view, the size S3h of the first dummy hole DH1h may be substantially a same as the size of the first contact hole CNT1.

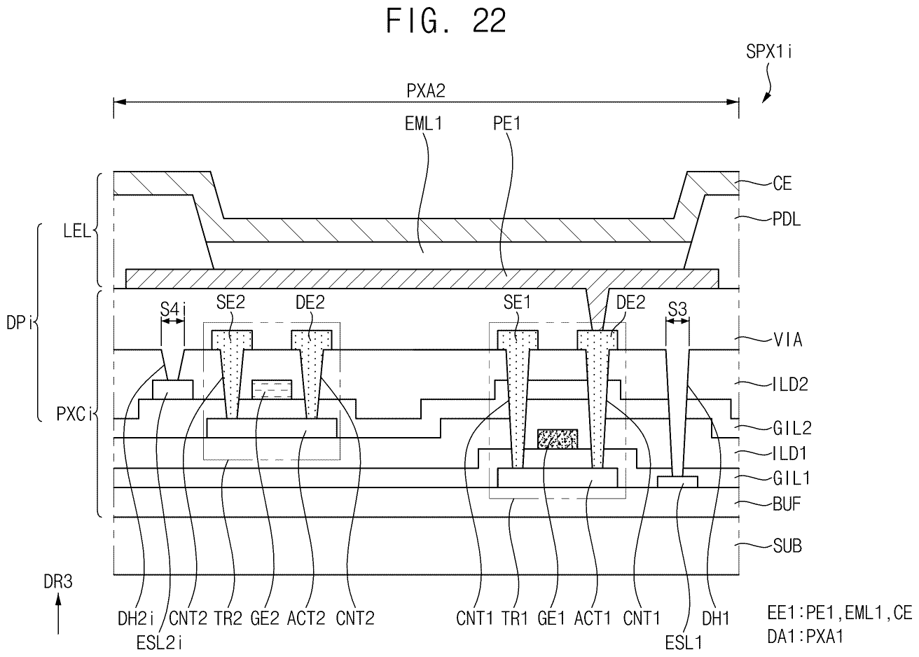

FIG. 22 is a cross-sectional view illustrating an example of a cross-section in the second display area of the first sub-pixel included in the display device of FIG. 17. A display panel DPi described with reference to FIG. 22 and the display panel DPg described with reference to FIG. 20 may be substantially a same or similar to each other, except that an arrangement of a second dummy hole DH2i and a second etch stop layer ESL2i in FIG. 22 is different from an arrangement of a first dummy hole DH1g and a first etch stop layer ESL1g in FIG. 20. Hereinafter, to the extent that an element is not described in detail with respect to this figure, it may be understood that the element is at least similar to a corresponding element that has been described elsewhere within the present disclosure referring to FIG. 20.

Referring to FIG. 22, a pixel circuit layer PXCi of the display panel DPi may include a second etch stop layer ESL2i, and a second dummy hole DH2i may be defined in the pixel circuit layer PXCi. The second etch stop layer ESL2i may be disposed in a same layer as a second gate electrode GE2. For example, the second etch stop layer ESL2i may include a same material as the second gate electrode GE2 and may be formed through a same process. The second dummy hole DH2i may penetrate in the thickness direction (e.g., in the third direction DR3) through a second interlayer insulating layer ILD2.

In the disclosure, the first gate insulating layer GIL1, the first interlayer insulating layer ILD1, the second gate insulating layer GIL2, and the second interlayer insulating layer ILD2 may be referred to as an insulator. In the disclosure, the second dummy hole DH2i may be referred to as a third dummy hole, and the second etch stop layer ESL2i may be referred to as a third etch stop layer.

In an embodiment, in a plan view, a size S4i of the second dummy hole DH2i may be different from a size of a second contact hole CNT2. In an embodiment, in a plan view, the size S4i of the second dummy hole DH2i may be substantially a same as the size of the second contact hole CNT2.

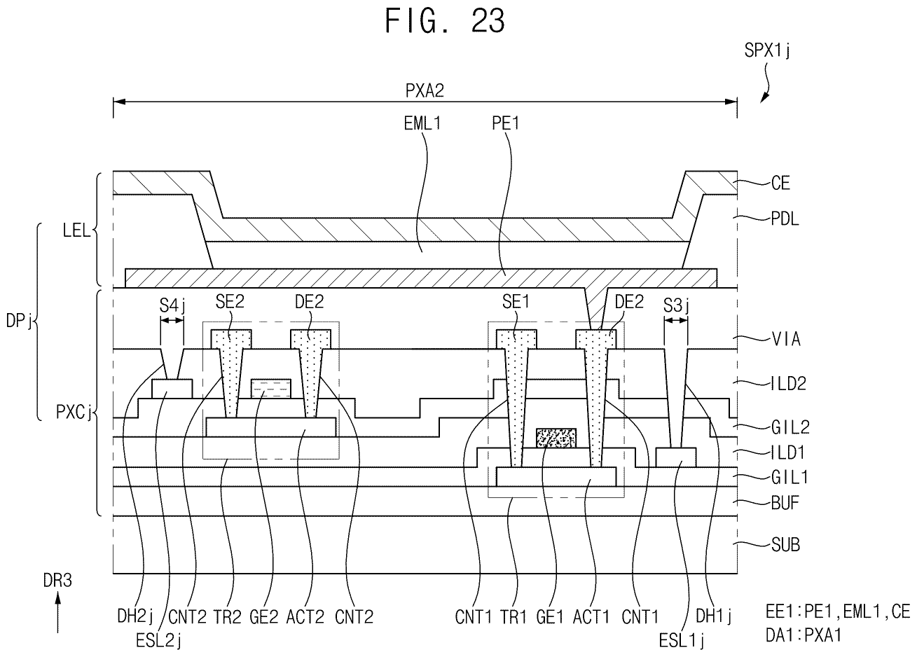

FIG. 23 is a cross-sectional view illustrating an example of a cross-section in the second display area of the first sub-pixel included in the display device of FIG. 17. A display panel DPj described with reference to FIG. 23 and the display panel DPg described with reference to FIG. 20 may be substantially a same or similar to each other, except that an arrangement of a first dummy hole DH1j, a second dummy hole DH2j, a first etch stop layer ESL1j, and a second etch stop layer ESL2j in FIG. 23 is different from an arrangement of the first dummy hole DH1g, the second dummy hole DH2g, the first etch stop layer ESL1g, and the second etch stop layer ESL2g in FIG. 20. Hereinafter, to the extent that an element is not described in detail with respect to this figure, it may be understood that the element is at least similar to a corresponding element that has been described elsewhere within the present disclosure referring to FIG. 20.

Referring to FIG. 23, a pixel circuit layer PXCj of the display panel DPj may include a first etch stop layer ESL1j and a second etch stop layer ESL2j, and a first dummy hole DH1j and a second dummy hole DH2j may be defined in the pixel circuit layer PXCj. The first etch stop layer ESL1j may be disposed in a same layer as a first gate electrode GE1. For example, the first etch stop layer ESL1j may include a same material as the first gate electrode GE1 and may be formed through a same process. The first dummy hole DH1j may penetrate in the thickness direction (e.g., in the third direction DR3) through a first interlayer insulating layer ILD1, a second gate insulating layer GIL2, and a second interlayer insulating layer ILD2.

In the disclosure, the first interlayer insulating layer ILD1, the second gate insulating layer GIL2, and the second interlayer insulating layer ILD2 may be referred to as an insulator. In the disclosure, the second dummy hole DH2j may be referred to as a third dummy hole, and the second etch stop layer ESL2j may be referred to as a third etch stop layer.

The second etch stop layer ESL2j may be disposed in a same layer as a second gate electrode GE2. For example, the second etch stop layer ESL2j may include a same material as the second gate electrode GE2 and may be formed through a same process. The second dummy hole DH2j may penetrate in the thickness direction (e.g., in the third direction DR3) through the second interlayer insulating layer ILD2.

In an embodiment, in a plan view, a size S3j of the first dummy hole DH1j may be different from a size of a first contact hole CNT1. In an embodiment, in a plan view, the size S3j of the first dummy hole DH1j may be substantially a same as the size of the first contact hole CNT1. In an embodiment, in a plan view, a size S4j of the second dummy hole DH2j may be different from a size of a second contact hole CNT2. In an embodiment, in a plan view, the size S4j of the second dummy hole DH2j may be substantially a same as the size of the second contact hole CNT2.

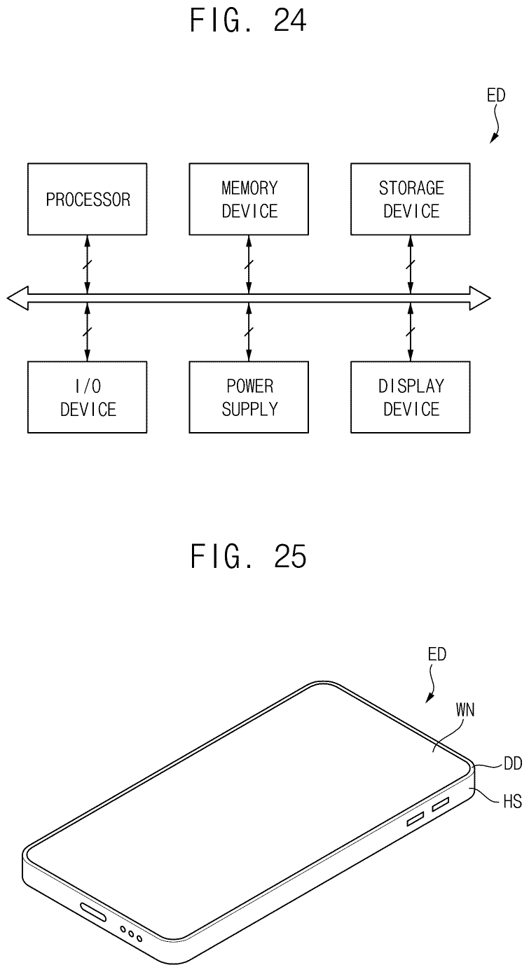

FIG. 24 is a block diagram illustrating an electronic device according to an embodiment of the disclosure. FIG. 25 is a diagram illustrating an example in which the electronic device of FIG. 24 is implemented as a smartphone.

Referring to FIGS. 24 and 25, the electronic device ED may include a processor, a memory device, a storage device, an input/output device, a power supply, and a display device. The display device included in the electronic device ED may be the display device DD, DD1 of FIGS. 1, 2, and 17. In addition, the electronic device ED may further include several ports capable of communicating with a video card, a sound card, a memory card, a USB device, or other systems.

The processor may perform specific calculations or tasks. According to an embodiment, the processor may be a microprocessor, a central processing unit, an application processor, or the like. The processor may be connected to other components via an address bus, a control bus, a data bus, and the like. According to an embodiment, the processor may also be connected to an expansion bus, such as a Peripheral Component Interconnect (PCI) bus. The processor may output data control signals and image data to the timing controller.

The memory device may store data necessary for the operation of the electronic device ED. For example, the memory device may include nonvolatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM), a ferroelectric random access memory (FRAM) device, and/or a volatile memory device such as a dynamic random access memory (DRAM) device, a static random access memory (SRAM) device, a mobile DRAM device, and the like.

The storage device may include a solid state drive (SSD), a hard disk drive (HDD), a CD-ROM, and the like. The input/output device may include an input means such as a keyboard, a keypad, a touchpad, a touchscreen, a mouse, and the like., and an output means such as a speaker, a printer, and the like. According to an embodiment, the display device may be included in the input/output device. The power supply may supply power required for the operation of the electronic device ED. The display device may be connected to other components through the buses or other communication links.

In an embodiment, as illustrated in FIG. 25, the electronic device ED may be implemented as a smartphone. The electronic device ED may include a cover window WN, a display device DD, and a housing HS.

The cover window WN may cover the display device DD. For example, the cover window WN may be disposed on the display areas of the display device DD (e.g., the first display area DA1 and the second display area DA2 of FIG. 1) to cover the display device DD. Accordingly, the cover window WN may protect the display area of the display device DD where an image is displayed.

The housing HS may surround the display device DD. For example, the display device DD may be accommodated in the housing HS to display an image. The housing HS may cover the side and bottom of the display device DD. Accordingly, the housing HS may supplement the rigidity of the display device DD to protect the display device DD from external impact.

A functional module such as a camera module or a sensor module may be accommodated inside the housing HS. Accordingly, the functional module may be electrically connected to the display device DD to perform a specific function. Type or arrangement of the functional module according to the embodiments of the present disclosure is not necessarily limited thereto.

However, this is exemplary, and the electronic device ED, according to embodiments of the present disclosure, may not necessarily be limited thereto. For example, the electronic device ED may be implemented as a mobile phone, a video phone, a smart pad, a smart watch, a tablet computer, a vehicle display, a computer monitor, a notebook/laptop computer, a head-mounted display device, and the like. In addition, the electronic device ED may be a car.

As described above, in the electronic device ED, according to an embodiment of the present disclosure, the housing HS may accommodate a display device (e.g., the display device DD, DD1 of FIGS. 1 and 17 or the display device DD of FIG. 25) that displays an image, and the cover window WN may cover the display device DD. Therefore, the durability of the display device DD may be increased through the electronic device ED, and the image with increased display quality may be continuously and easily provided to the user.

Although the devices according to the embodiments have been described with reference to the drawings, the illustrated embodiments are examples, and may be modified and changed by a person having ordinary knowledge in the relevant technical field without departing from the technical spirit of the present disclosure.

What is claimed is:

1. A display device, comprising:
a substrate including a first display area that includes a first pixel area and a second display area, wherein at least a portion of the second display area is surrounded by the first display area, and wherein the second display area includes a transmission area and a second pixel area;
a first etch stop layer disposed in the second pixel area on the substrate;
a first transistor disposed in the second pixel area on the substrate;
a light-emitting element disposed in the second pixel area on the first transistor, electrically connected to the first transistor, and including a pixel electrode, a light-emitting layer and a common electrode; and
an insulator disposed in both the first display area and the second display area on the first etch stop layer, exposing an upper surface of the first etch stop layer, and defining a first dummy hole overlapping the pixel electrode, in a plan view.

2. The display device of claim 1, wherein the first dummy hole is spaced apart from the transmission area, in the plan view.

3. The display device of claim 1, further comprising:
a second etch stop layer disposed in the first pixel area on the substrate,
wherein in the insulator, a second dummy hole, which exposes an upper surface of the second etch stop layer and is disposed in the first pixel area, is defined, and
wherein the first dummy hole disposed in the second pixel area is part of a plurality of first dummy holes, the second dummy hole disposed in the first display area is part of a plurality of second dummy holes, and a number of first dummy holes of the plurality of first dummy holes is greater than a number of second dummy holes of the plurality of second dummy holes.

4. The display device of claim 1, wherein the first transistor includes:
a first active layer disposed on the substrate;
a first gate electrode disposed on the first active layer;
a first source electrode disposed on the first gate electrode; and
a first drain electrode disposed on the first gate electrode.

5. The display device of claim 4, wherein the insulator includes:
a gate insulating layer disposed on the first active layer; and
an interlayer insulating layer disposed on the first gate electrode.

6. The display device of claim 5, wherein the first etch stop layer is disposed in a same layer as the first active layer, and
wherein the first dummy hole penetrates the gate insulating layer and the interlayer insulating layer in a thickness direction.

7. The display device of claim 5, wherein the first etch stop layer is disposed in a same layer as the first gate electrode, and
wherein the first dummy hole penetrates the interlayer insulating layer in a thickness direction.

8. The display device of claim 5, wherein the first source electrode and the first drain electrode contact the first active layer through a contact hole which penetrates the gate insulating layer and the interlayer insulating layer in a thickness direction, and
wherein in the plan view, a size of the contact hole is less than a size of the first dummy hole.

9. The display device of claim 5, wherein the first source electrode and the first drain electrode contact the first active layer through a contact hole which penetrates the gate insulating layer and the interlayer insulating layer in a thickness direction, and
wherein, in the plan view, a size of the contact hole is greater than a size of the first dummy hole.

10. The display device of claim 4, further comprising:
a second transistor disposed in the second pixel area on the substrate; and
a third etch stop layer disposed in the second pixel area on the substrate,
wherein the second transistor includes:
a second active layer disposed on the first source electrode and the first drain electrode;
a second gate electrode disposed on the second active layer;
a second source electrode disposed on the second gate electrode; and
a second drain electrode disposed on the second gate electrode.

11. The display device of claim 10, wherein the insulator includes:
a first gate insulating layer disposed on the first active layer;
a first interlayer insulating layer disposed on the first gate electrode;
a second gate insulating layer disposed on the second active layer; and
a second interlayer insulating layer disposed on the second gate insulating layer,
wherein a third dummy hole, which penetrates at least a portion of the insulator in a thickness direction and exposes an upper surface of the third etch stop layer, is defined in the insulator.

12. The display device of claim 11, wherein the first etch stop layer is disposed in a same layer as the first active layer, and
wherein the first dummy hole penetrates the first gate insulating layer, the first interlayer insulating layer, the second gate insulating layer, and the second interlayer insulating layer in a thickness direction.

13. The display device of claim 11, wherein the first etch stop layer is disposed in a same layer as the first gate electrode, and
wherein the first dummy hole penetrates the first interlayer insulating layer, the second gate insulating layer, and the second interlayer insulating layer in a thickness direction.

14. The display device of claim 11, wherein the third etch stop layer is disposed in a same layer as the second active layer, and
wherein the third dummy hole penetrates the second gate insulating layer and the second interlayer insulating layer in a thickness direction.

15. The display device of claim 11, wherein the third etch stop layer is disposed in a same layer as the second gate electrode, and
wherein the third dummy hole penetrates the second interlayer insulating layer in a thickness direction.

16. A display device, comprising:
a substrate including a first display area that includes a first pixel area and a second display area, wherein at least a portion of the second display area is surrounded by the first display area, and wherein the second display area includes a transmission area and a second pixel area;
an etch stop layer disposed in the second pixel area on the substrate;
a transistor disposed in the second pixel area on the substrate;
a light-emitting element disposed in the second pixel area on the transistor, electrically connected to the transistor, and including a pixel electrode, a light-emitting layer, and a common electrode;
a plurality of light blockers disposed in the first display area and the second display area on the light-emitting element; and
an insulator disposed in the first display area and the second display area on the etch stop layer and in which a dummy hole, which exposes an upper surface of the etch stop layer and overlaps the plurality of light blockers in a plan view, is defined.

17. The display device of claim 16, further comprising:
a plurality of gate lines disposed in both the first display area and the second display area on the substrate, and extending in a first direction; and
a plurality of data lines disposed in the first display area and the second display area on the substrate, and extending in a second direction crossing the first direction,
wherein the dummy hole is spaced apart from the plurality of gate lines and the plurality of data lines, in the plan view.

18. An electronic device, comprising:
a housing;
a display device housed in the housing, configured to display an image, and including:
a substrate including a first display area that includes a first pixel area and a second display area, wherein at least a portion of the second display area is surrounded by the first display area, and wherein the second display area includes a transmission area and a second pixel area;
an etch stop layer disposed in the second pixel area on the substrate;
a transistor disposed in the second pixel area on the substrate;
a light-emitting element disposed in the second pixel area on the transistor, electrically connected to the transistor, and including a pixel electrode, a light-emitting layer, and a common electrode;
a plurality of light blockers disposed in the first display area and the second display area, on the light-emitting element; and
an insulator disposed in the first display area and the second display area on the etch stop layer and in which a first dummy hole, which exposes an upper surface of the etch stop layer, and overlaps the plurality of light blockers in a plan view or overlaps the plurality of light blockers, is defined; and
a cover window covering the display device.

19. The electronic device of claim 18, wherein the first dummy hole is spaced apart from the transmission area in the plan view.

20. The electronic device of claim 19, wherein the display device further including:
a second etch stop layer disposed in the first pixel area on the substrate,
wherein a second dummy hole, which exposes an upper surface of the second etch stop layer and disposed in the first pixel area, is defined in the insulator, and
wherein the first dummy hole disposed in the second display area is part of a plurality of first dummy holes, the second dummy hole disposed in the first display area is part of a plurality of second dummy holes, and a number of first dummy holes of the plurality of first dummy holes is greater than a number of second dummy holes of the plurality of second dummy holes.
